(19) United States
(12) Patent Application Publication
(10) Pub. No.: US 2003/0209815 A1
(43) Pub. Date: Nov. 13, 2003

(54) Semiconductor device and its manufacturing method

(76) Inventors: Fujio Ito, Hanno (JP); Hiromichi Suzuki, Tokyo (JP)

Correspondence Address: Mattingly, Stanger & Malur, P.C., Suite 370, 1800 Diagonal Road, Alexandria, VA, 22314, US

(21) Appl. No.: 10/430,189

(22) Filed: May 7, 2003

(30) Foreign Application Priority Data
May 10, 2002 (JP) P2002-134952

(51) Int. Cl. H01L 23/544

(52) U.S. Cl. 257/797

(57) ABSTRACT

In order to improve the mounting accuracy of QFN (Quad Flat Non-leaded package) having external connection terminals on a rear surface of the package, a semiconductor device and its manufacturing method are provided. In the QFN, notch sections are provided in the two diagonal corner portions on the front surface of the sealing body. Reference marks with a circular form are formed in the parts of the suspension leads exposed from the notch sections so that the positions of the reference marks can be optically detected from above the sealing body when mounting the QFN to the wiring board. The reference marks are formed by the etching to remove the parts of the metal plate that constitutes the suspension leads or by pressing the parts to punch them.

### CROSS-REFERENCES TO RELATED APPLICATIONS

The following application, is being filed concurrently, and the disclosure of the application is incorporated by reference into this application in their entirety for all purposes:

U.S. patent application Ser. No. 10/299,768 (filed on Nov. 20, 2002) entitled “SEMICONDUCTOR DEVICE AND METHOD OF MANUFACTURING THE SAME”

### TECHNICAL FIELD OF THE INVENTION

The present invention relates to a semiconductor device and its manufacturing technique. More particularly, the present invention relates to a technique for accurately mounting a resin-sealing type semiconductor device having external connection terminals on a rear surface of a package to a wiring board.

### BACKGROUND OF THE INVENTION

QFN (Quad Flat Non-leaded package) can be taken as an example of a resin package obtained by sealing a semiconductor chip mounted on a lead frame in a sealing body made of molding resin.

The QFN has a structure in which one end portions of a plurality of leads electrically connected to a semiconductor chip via bonding wires are exposed on a rear surface (bottom surface) of an outer portion of the sealing body and the exposed parts form the external connection terminals, and the bonding wires are connected to the surfaces opposite to the exposed surfaces of the terminals, that is, the surfaces of the terminals inside the sealing body, thereby electrically connecting the terminals and the semiconductor chip. Thus, the QFN is mounted on a wiring board by soldering these terminals to electrodes (footprints) of the wiring board. This structure has an advantage that the mounting area thereof can be reduced in comparison with QFP (Quad Flat Package) in which leads extending in a lateral direction from side surfaces of a package (sealing body) form the terminals.

The QFN is described in, for example, the gazette of Japanese Patent Laid-Open No. 2001-189410 and Japanese Patent No. 3072291.

### SUMMARY OF THE INVENTION

In the case of the QFP in which leads extending in a lateral direction from the side surfaces of a sealing body form the terminals, the positions of the external connection terminals can be optically detected from above when mounting it to the wiring board. Therefore, it is possible to easily align the wiring board with the external connection terminals.

Contrary to this, in the case of the QFN in which the external connection terminals are arranged on the rear surface (bottom surface) of the sealing body, the positions of the external connection terminals cannot be optically detected from above. Therefore, the expensive alignment apparatus provided with a complicated optical system for optically detecting the positions of the external connection terminals obliquely from below is required, which causes the increase of the mounting cost of the QFN.

An object of the present invention is to provide a technique capable of improving the mounting accuracy of the QFN without using any expensive alignment apparatus provided with a complicated optical system.

The above and other objects and novel characteristics of the present invention will be apparent from the description and the accompanying drawings of this specification.

The typical ones of the inventions disclosed in this application will be briefly described as follows.

An aspect of the present invention is a semiconductor device, which comprises: a semiconductor chip; a die pad on which the semiconductor chip is mounted; suspension leads to support the die pad; a plurality of leads arranged around the die pad; a plurality of wires to electrically connect the semiconductor chip to the leads; and a sealing body for sealing the semiconductor chip, the die pad, the suspension leads, the plurality of leads, and the plurality of wires, wherein external connection terminals protruded from a rear surface of the sealing body to the outside are selectively provided on each of the plurality of leads; wherein a part of the suspension leads is exposed from an upper surface of the sealing body to the outside; and wherein a reference mark used for the alignment between the external connection terminals and a wiring board is formed on the part of the suspension leads exposed from the upper surface of the sealing body to the outside.

Consequently, it is possible to accurately align the external connection terminals arranged on the rear surface of the sealing body with the wiring board by optically detecting the positions of the reference marks from above when mounting the semiconductor device on a wiring board.

### BRIEF DESCRIPTIONS OF THE DRAWINGS

FIG. 1 is a plan view showing an outward appearance (front surface side) of a semiconductor device according to an embodiment of the present invention;

FIG. 2 is a plan view showing an outward appearance (rear surface side) of the semiconductor device according to an embodiment of the present invention;

FIG. 3 is a plan view showing an inner structure (front surface side) of the semiconductor device according to an embodiment of the present invention;

FIG. 4 is a plan view showing an inner structure (rear surface side) of the semiconductor device according to an embodiment of the present invention;

FIG. 5 is a sectional view of the semiconductor device according to an embodiment of the present invention;

FIG. 6 is a sectional view of the semiconductor device according to an embodiment of the present invention;

FIG. 7 is an entire plan view of a lead frame used in the manufacture of the semiconductor device according to an embodiment of the present invention;

FIG. 8 is an enlarged plan view showing a part of the leaf frame shown in FIG. 7;

FIG. 9 is a sectional view showing the manufacturing method of the lead frame shown in FIG. 7;

FIG. 10 is a plan view showing the principal part of the lead frame, which illustrates the shape of reference marks formed in the parts of suspension leads;

FIG. 11 is a plan view showing the principal part of the lead frame, which illustrates the shape of reference marks formed in the parts of suspension leads;

FIG. 12 is a plan view showing the principal part of the lead frame, which illustrates the shape of reference marks formed in the parts of suspension leads;

FIG. 13 is a plan view showing the principal part of the lead frame after adhering the semiconductor chip, which illustrates the manufacturing method of the semiconductor device according to an embodiment of the present invention;

FIG. 14 is a plan view showing the principal part of the lead frame after the wire bonding, which illustrates the manufacturing method of the semiconductor device according to an embodiment of the present invention;

FIG. 15 is a schematic sectional view showing the manufacturing method of the semiconductor device according to an embodiment of the present invention;

FIG. 16 is a sectional view showing the principal part of a molding die and the lead frame, which illustrates the manufacturing method of the semiconductor device according to an embodiment of the present invention;

FIG. 17 is a sectional view showing the principal part of the molding die and the lead frame, which illustrates the manufacturing method of the semiconductor device according to an embodiment of the present invention;

FIG. 18 is a sectional view showing the principal part of the molding die and the lead frame, which illustrates the manufacturing method of the semiconductor device according to an embodiment of the present invention;

FIG. 19 is a plan view showing the contact portion between the molding die (upper die) and the lead frame, which illustrates the manufacturing method of the semiconductor device according to an embodiment of the present invention;

FIG. 20 is a plan view schematically showing the positions of gates of the molding die and the flowing directions of resin injected into cavities, which illustrates the manufacturing method of the semiconductor device according to an embodiment of the present invention;

FIG. 21 is a plan view of the lead frame after the molding, which illustrates the manufacturing method of the semiconductor device according to an embodiment of the present invention;

FIG. 22 is a sectional view of the lead frame taken along the line X-X′ in FIG. 21;

FIG. 23 is a plan view of the lead frame after the molding, which illustrates the manufacturing method of the semiconductor device according to an embodiment of the present invention;

FIG. 24 is a plan view showing the state where the semiconductor device according to an embodiment of the present invention is mounted on a wiring board together with other surface mounting type semiconductor devices;

FIG. 25 is a plan view showing the principal part of a lead frame used in the manufacture of a semiconductor device according to another embodiment of the present invention;

FIG. 26 is a sectional view showing the principal part of the lead frame used in the manufacture of the semiconductor device according to another embodiment of the present invention;

FIG. 27 is a sectional view showing the manufacturing method of the lead frame shown in FIG. 25;

FIG. 28 is a sectional view showing the principal part of the lead frame, which illustrates the manufacturing method of the semiconductor device according to another embodiment of the present invention;

FIG. 29 is a plan view showing the principal part of the lead frame after the molding, which illustrates the manufacturing method of the semiconductor device according to another embodiment of the present invention;

FIG. 30 is a plan view showing an outward appearance (front surface side) of a semiconductor device according to still another embodiment of the present invention;

FIG. 31 is a plan view showing an outward appearance (rear surface side) of the semiconductor device according to still another embodiment of the present invention;

FIG. 32 is a plan view showing an inner structure (front surface side) of the semiconductor device according to still another embodiment of the present invention;

FIG. 33 is a plan view showing an inner structure (rear surface side) of the semiconductor device according to still another embodiment of the present invention;

FIG. 34 is a sectional view of the semiconductor device according to still another embodiment of the present invention;

FIG. 35 is a sectional view of the semiconductor device according to still another embodiment of the present invention;

FIG. 36 is a sectional view of the semiconductor device according to still another embodiment of the present invention;

FIG. 37 is an entire plan view of the lead frame used in the manufacture of the semiconductor device according to still another embodiment of the present invention;

FIG. 38 is a sectional view showing the manufacturing method of the lead frame shown in FIG. 37;

FIG. 39 is a sectional view showing the manufacturing method of the lead frame shown in FIG. 37;

FIG. 40 is a sectional view showing the principal part of a press die and the lead frame, which illustrates the manufacturing method of the semiconductor device according to still another embodiment of the present invention;

FIG. 41 is a plan view showing the principal part of the lead frame after the molding, which illustrates the manufacturing method of the semiconductor device according to still another embodiment of the present invention;

FIG. 42 is a plan view showing the principal part of the lead frame after the molding, which illustrates the manufacturing method of the semiconductor device according to still another embodiment of the present invention; and

FIG. 43 is a sectional view showing the principal part of the lead frame after the molding, which illustrates the manufacturing method of the semiconductor device according to still another embodiment of the present invention.

### DESCRIPTION OF THE PREFERRED EMBODIMENTS

Hereinafter, embodiments of the present invention will be described in detail with reference to the accompanying drawings. Note that components having the same function are denoted by the same reference symbols throughout the drawings for describing the embodiment, and the repetitive description thereof is omitted. Also, in the following embodiments, the descriptions of the same or similar components are not repeated in principle except the case that it is particularly required.

(First Embodiment)

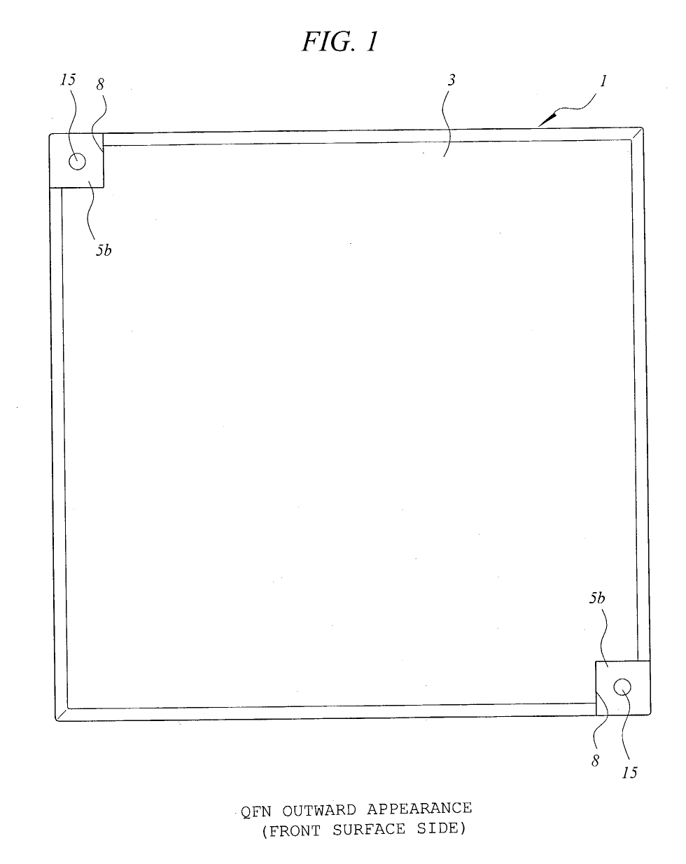

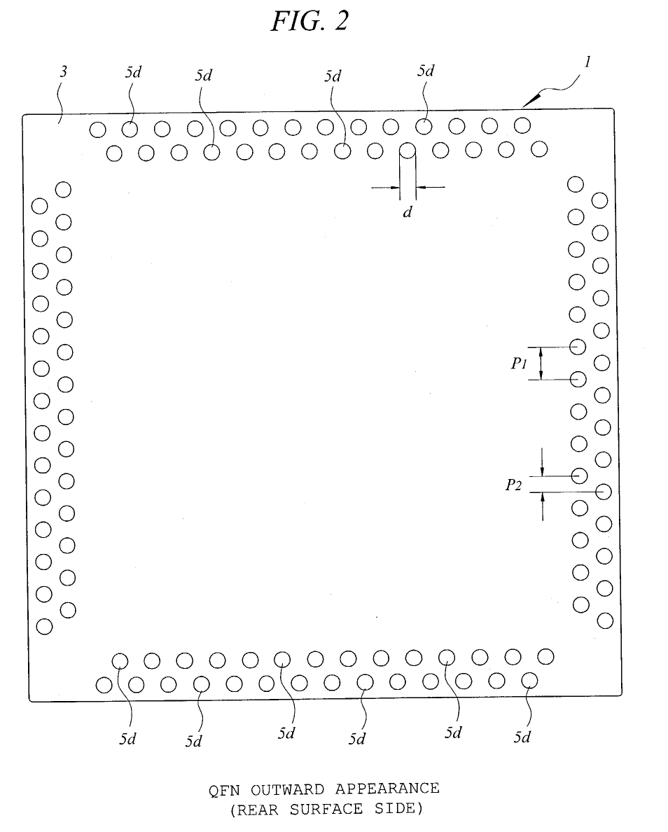

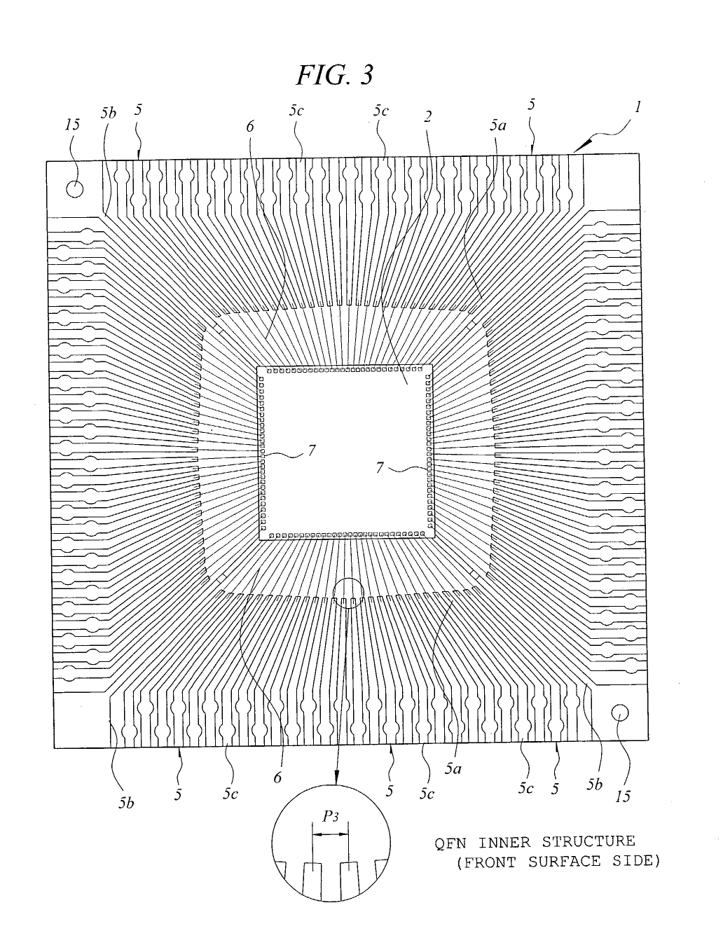

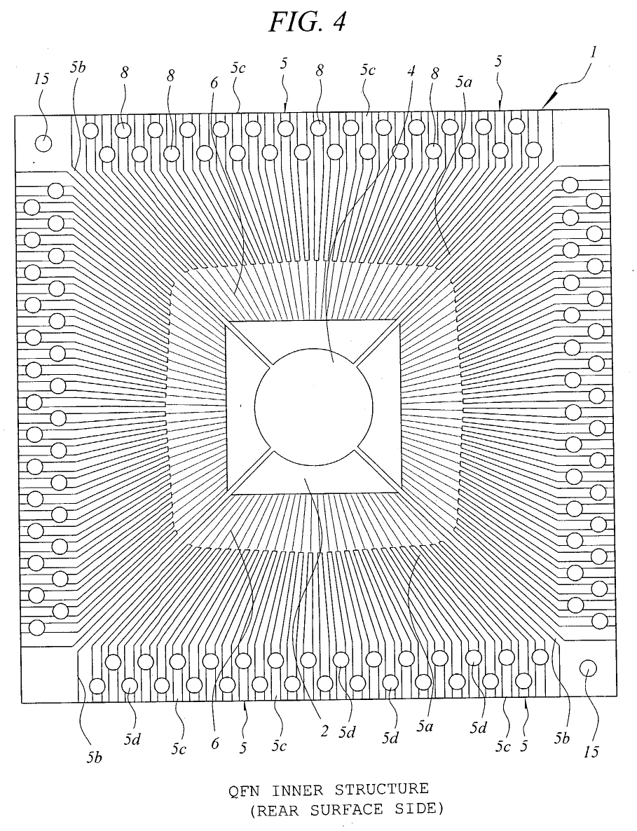

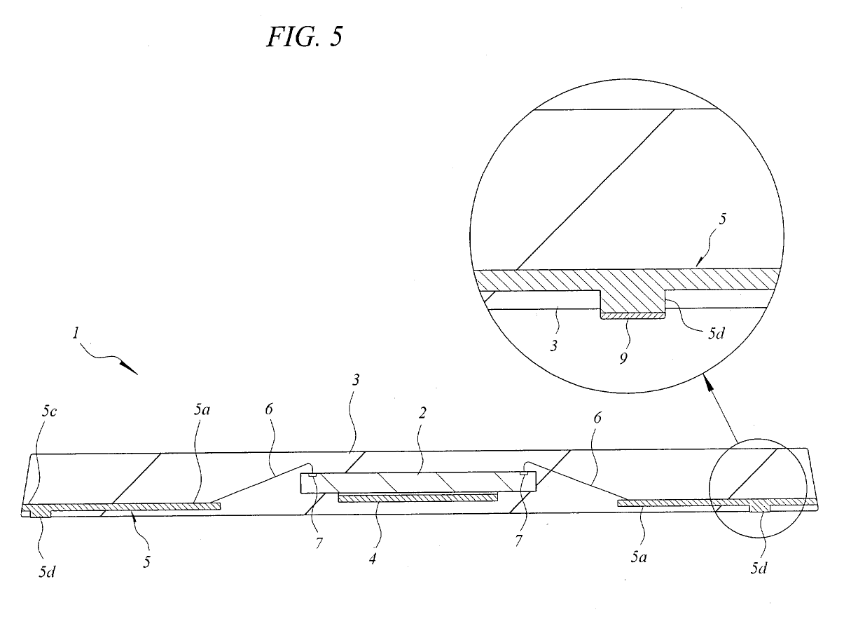

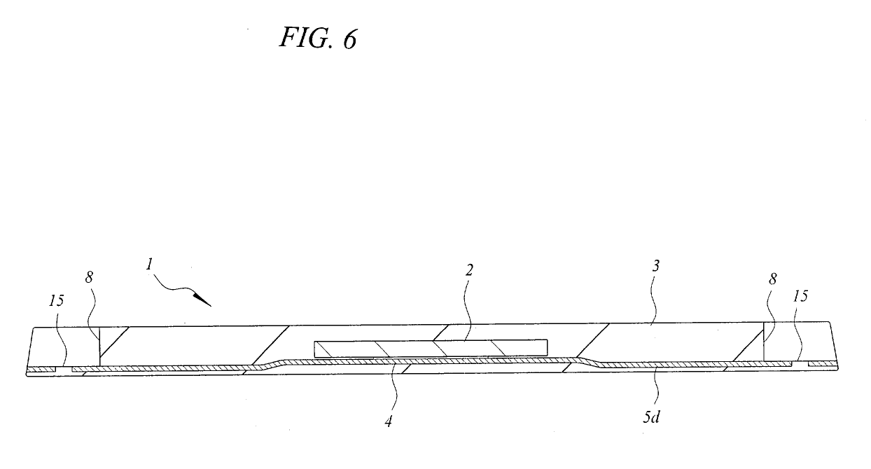

FIG. 1 is a plan view showing an outward appearance (front surface side) of a QFN according to the first embodiment, FIG. 2 is a plan view showing an outward appearance (rear surface side) of the QFN, FIG. 3 is a plan view showing an inner structure (front surface side) of the QFN, FIG. 4 is a plan view showing an inner structure (rear surface side) of the QFN, and FIGS. 5 and 6 are sectional views of the QFN.

The QFN 1 in this embodiment has a surface mounting package structure in which one semiconductor chip 2 is sealed in a sealing body made of synthetic resin, and the outside dimensions of the sealing body 3 are, for example, length 12 mm, width 12 mm, and height 0.9 mm.

The semiconductor chip 2 mounted on a metal die pad 4 is disposed in a center portion of the sealing body 3. The outside dimensions of the semiconductor chip 2 are, for example, length 4 mm, width 4 mm, and height 0.28 mm. Also, the diameter of the die pad 4 is designed to be smaller than the diameter of the semiconductor chip 2 so as to mount the various semiconductor chips 2 with the length of a side from 4 to 7 mm. More specifically, the die pad 4 has a so-called small-tab structure, and the die pad 4 in this embodiment has a diameter of 3 mm.

The die pad 4 on which the semiconductor chip 2 is mounted is supported by four suspension leads 5b. One end portions of the suspension leads 5b (on the side near the semiconductor chip 2) are connected to the die pad 4, and the other end portions thereof are extended to the corner portions of the sealing body 3. The width of the suspension lead 5b in the corner portion of the sealing body 3 is designed to be larger than that of the other part of the suspension lead 5b.

A plurality of (for example, 116) leads 5 are arranged around the die pad 4 so as to surround the die pad 4. One end portions (on the side near the semiconductor chip 2) 5a of the leads 5 are electrically connected to bonding pads 7 on a main surface of the semiconductor chip 2 via Au wires 6. Also, the other end portions 5c thereof are ended at the side surface of the sealing body 3. The thickness of the leads 5, the die pad 4, and the suspension leads 5b is about 75 μm.

As shown in FIG. 3, one end portion 5a of each of the leads 5 is extended to the position near the semiconductor chip 2 so as to reduce the distance between the leads 5 and the semiconductor chip 2, and the pitch (P₃) of the tips thereof is set to be smaller than the pitch of the other end portions 5c (for example, 0.18 mm to 0.2 mm). By extending the one end portions 5a of the leads 5 to the positions near the die pad 4 as described above, it is possible to reduce the length of the Au wires 6 (for example, 3 mm or shorter) that connect the leads 5 and the bonding pads 7. Consequently, even in the case where the number of pins of the QFN 1 is increased or the case where the pitch of the leads 5, that is, the distance between the Au wires 6 is reduced as a result of the increase of the number of pins of the QFN 1, it is possible to reduce the occurrence of the short circuit in which the Au wires 6 are contacted to each other in the manufacturing process of the QFN 1 (for example, in the wire bonding process and resin molding process).

As shown in FIG. 2, a plurality of (for example, 116) external connection terminals 5d are provided on a rear surface (board mounting surface) of the QFN 1. These external connection terminals 5d are arranged in two lines in a zigzag pattern along each side of the sealing body 3, and tip portions of these terminals 5d are exposed and protruded from the rear surface of the sealing body 3 to the outside. Also, these terminals 5d are designed to have a width larger than that of the leads 5 so as to obtain the sufficient mounting area. The diameter (d) of the terminal 5d is 0.3 mm, the pitch (P₁) between the adjacent terminals 5d in the same line is 0.65 mm, and the pitch (P₂) between the adjacent terminals 5d in the different lines is 0.325 mm.

The terminal 5d is integrally formed with the lead 5, and the thickness of the lead 5 at the portion where the terminal 5d is formed is about 150 μm. A solder layer 9 is deposited by the plating method or the printing method on each tip portion of the terminals 5d protruded to the outside of the sealing body 3, and the thickness of the solder layer 9 is determined so that the height of the terminal 5d including that of the solder layer 9, that is, the amount of protrusion (standoff amount) from the rear surface of the sealing body 3 to the outside becomes at least 50 μm or larger. The QFN 1 in this embodiment is mounted on a wiring board by soldering the terminals 5d to the electrodes (footprints) on the wiring board.

As shown in FIGS. 1 and 6, notch sections 8 for exposing the other end portions of the suspension leads 5b are provided in each of the two diagonal corner portions of the front surface of the sealing body 3. Reference marks 15, for example, in a circular form are provided on the parts of the suspension leads 5b exposed from the notch sections 8, and the reference marks 15 can be optically recognized from the front surface side of the sealing body 3 when mounting the QFN 1 to the wiring board. The reference marks 15 are formed by the etching to remove the parts of the metal plate that constitutes the suspension leads 5b or by pressing and punching the parts of the plate.

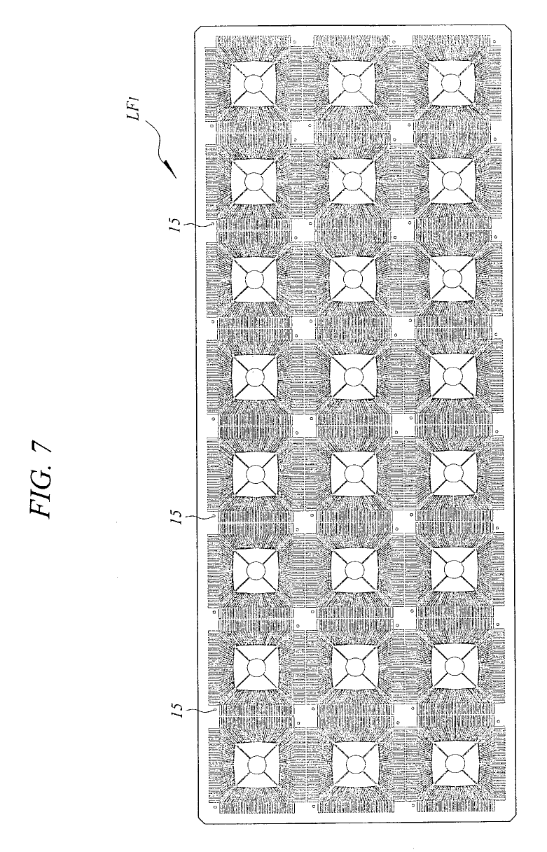

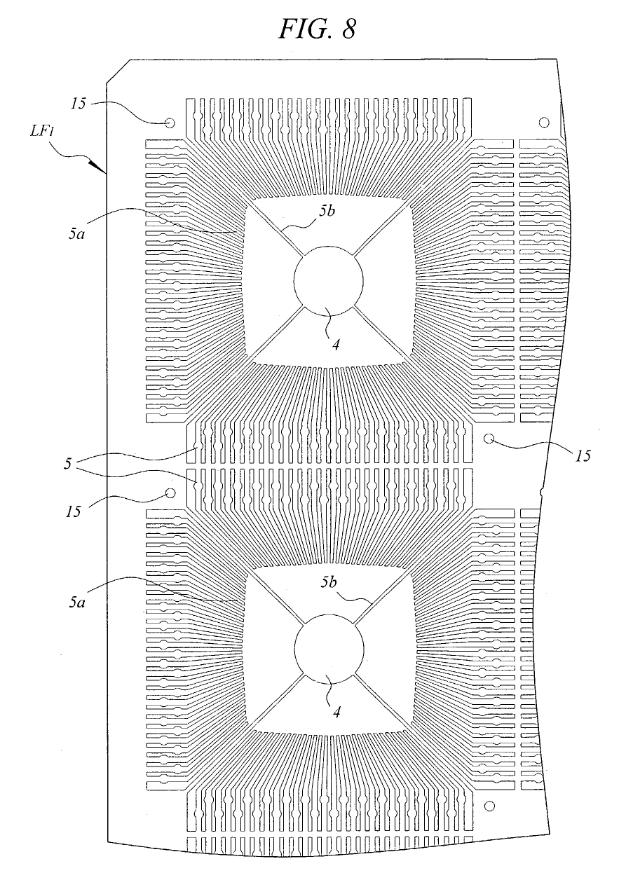

FIG. 7 is an entire plan view of a lead frame LF₁ used in the manufacture of the QFN 1 in this embodiment, and FIG. 8 is an enlarged plan view showing a part (a region equivalent to almost two QFN) of FIG. 7.

The lead frame LF₁ is composed of a metal plate made of Cu, Cu alloy, or Fe—Ni alloy, and above-described patterns such as die pads 4, leads 5, and suspension leads 5b are repeatedly formed laterally and longitudinally. More specifically, the lead frame LF₁ has a multiple structure in which a plurality of (for example, 24) semiconductor chips 2 can be mounted.

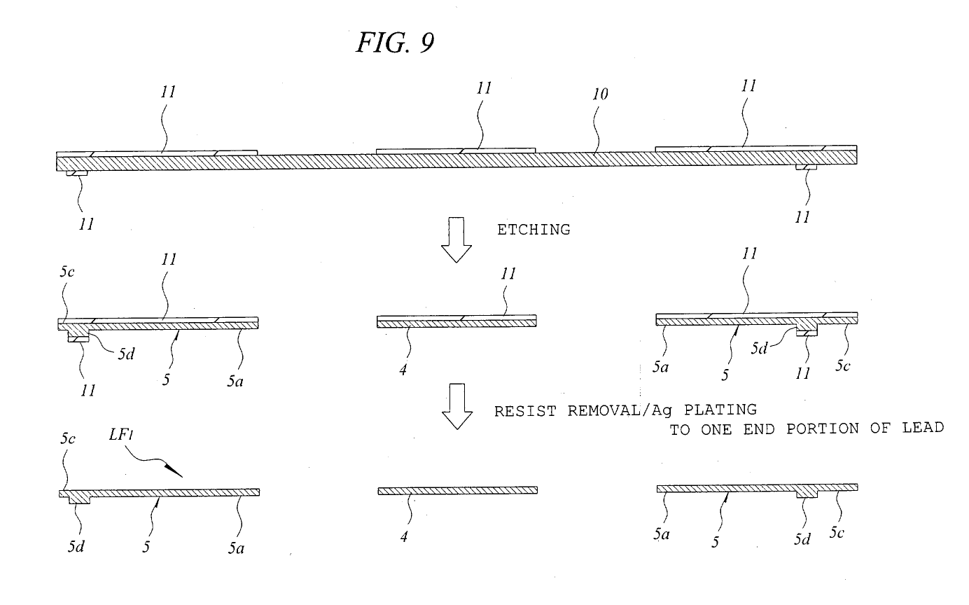

The lead frame LF₁ is manufactured in the following manner. That is, a metal plate 10 with a thickness of 150 μm made of Cu, Cu alloy, or Fe—Ni alloy is prepared as shown in FIG. 9, and one surface of the parts of the metal plate 10 where the die pad 4, the leads 5, and the suspension leads 5b are to be formed is covered with a photoresist film 11. Also, both surfaces of the parts of the metal plate 10 where the external connection terminals 5d are to be formed are covered with the photoresist film 11. Then, the metal plate 10 in this state is etched by the use of etching solution so as to reduce the thickness of the parts of the metal plate 10 where one surface thereof is covered with the photoresist film 11 to the half (about 75 μm) (half etching). By the etching in this manner, the parts of the metal plate 10 whose surfaces are not covered with the photoresist film 11 are completely removed, and the die pad 4, the leads 5, and the suspension leads 5b with a thickness of about 75 μm are formed in the regions where one surface of the metal plate 10 is covered with the photoresist film 11. In addition, since the metal plate 10 whose both surfaces are covered with the photoresist film 11 is not etched by the etching solution, the convex-shaped terminals 5d with a thickness the same as that before the etching (about 150 μm) are formed. Subsequently, the photoresist film 11 is removed, and then, the other end portions of the suspension leads 5b (not shown in FIG. 9) are pressed and punched to form the above-mentioned reference marks 15. Thereafter, the Ag plating is applied to the surface of the one end portion 5a of the lead 5. In this manner, the manufacture of the lead frame LF₁ is completed. Note that it is also possible to form the reference mark 15 simultaneously with the formation of the die pad 4, the leads 5, and the suspension leads 5b by the etching with using the photoresist film 11 as a mask.

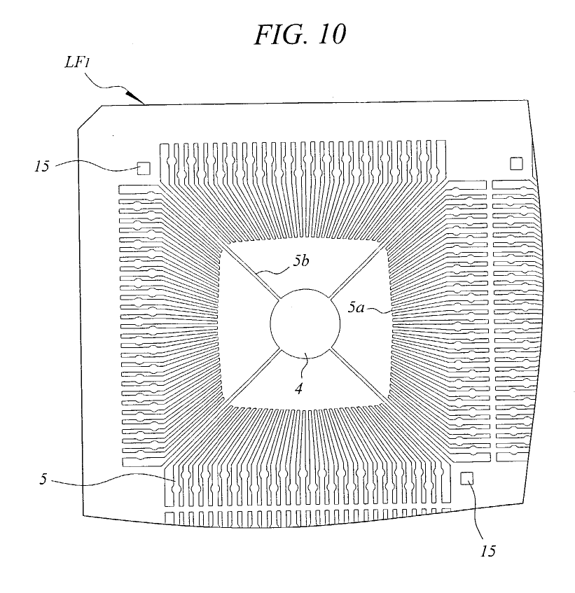

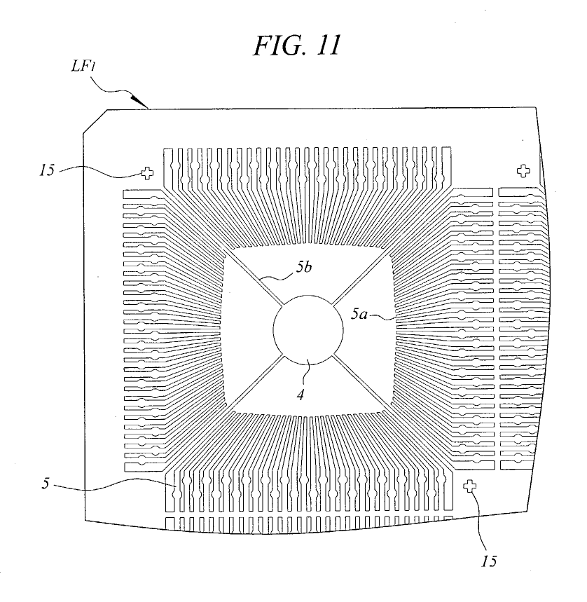

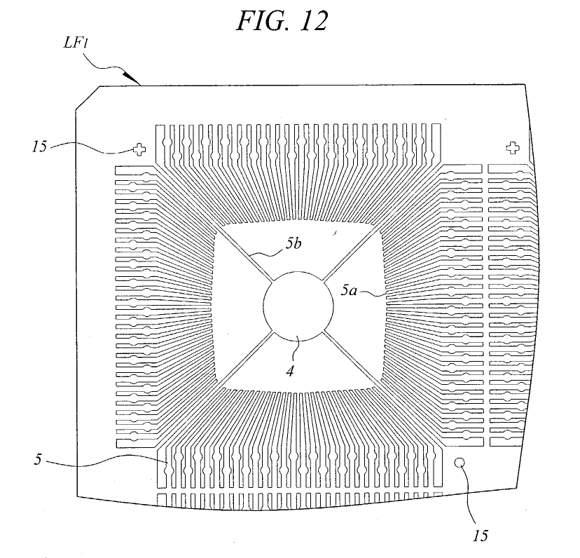

Any shapes such as a square shown in FIG. 10 and a cross shown in FIG. 11 are available as the shape of the reference mark 15 as long as it can be optically recognized from the front surface side of the sealing body 3. In addition, as shown in FIG. 12, the reference marks 15 provided in the two corner portions can be formed in different shapes from each other. By so doing, it is possible to easily detect the shift of the QFN 1 even when the QFN 1 is shifted 180 degrees on a surface horizontal to the mounting surface of the wiring board.

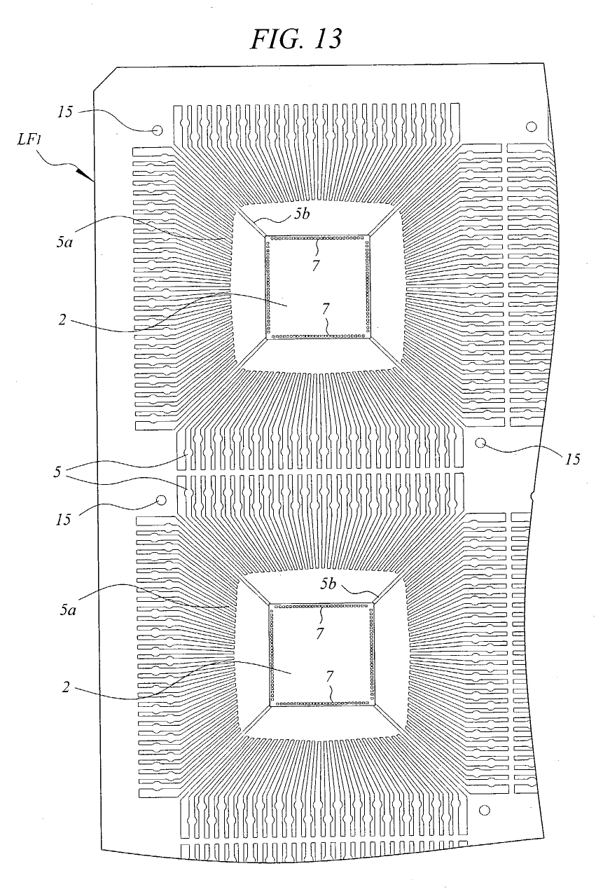

The QFN 1 is manufactured by the use of the abovementioned lead frame LF₁ in the following manner. First, the semiconductor chip 2 with the device forming surface thereof facing upward is mounted on the die pad 4 and the semiconductor chip 2 and the die pad 4 are adhered to each other by the use of Au paste or the epoxy resin adhesive as shown in FIG. 13.

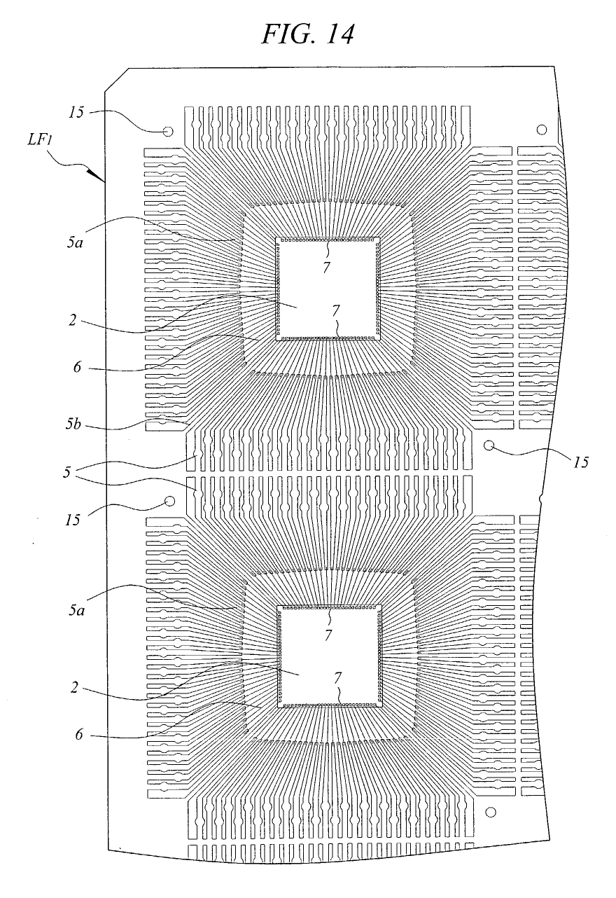

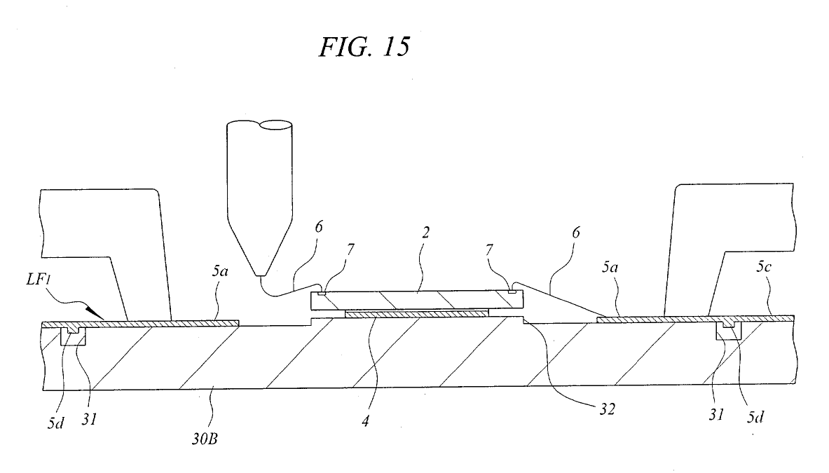

Next, as shown in FIG. 14, the bonding pads 7 of the semiconductor chip 2 and the one end portions 5a of the leads 5 are connected to each other by the Au wires 6 by using a known ball bonding machine. It is possible to stably hold the lead frame LF₁ by forming grooves 31 at the positions corresponding to the terminals 5d of a jig 30B which supports the lead frame LF₁ and forming protrusions 32 at the positions corresponding to the die pad 4 as shown in FIG. 15 when bonding the Au wires 6 or adhering the semiconductor chip 2 to the die pad 4. Therefore, it is possible to prevent the occurrence of misalignment between the Au wires 6 and the leads 5 and that between the semiconductor chip 2 and the die pad 4.

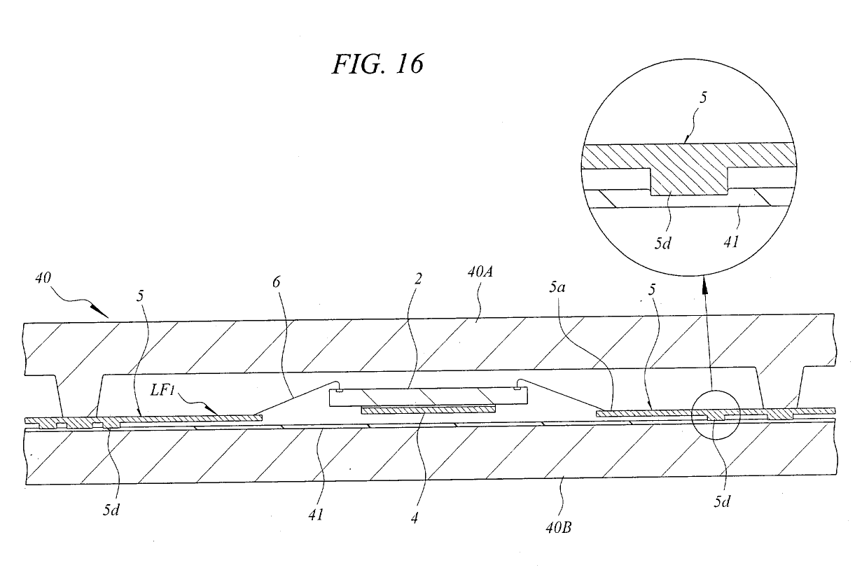

Next, the lead frame LF₁ is attached to a molding die 40 shown in FIG. 16 and the semiconductor chip 2 is sealed with resin. FIG. 16 is a sectional view showing a part of the molding die 40 (a region equivalent to one QFN).

When sealing the semiconductor chip 2 with resin by using the molding die 40, a thin resin sheet 41 is first laid on a surface of the lower die 40B, and the lead frame LF₁ is placed on the resin sheet 41. The lead frame LF₁ is placed, with the surface thereof on which the convex terminals 5d are formed facing downward, and the terminals 5d and the resin sheet 41 are brought into contact with each other. In this state, the resin sheet 41 and the lead frame LF₁ are sandwiched by an upper die 40A and the lower die 40B. By so doing, the terminals 5d located on the lower surface of the leads 5 press the resin sheet 41 by the pressing force from the molding die 40 (upper die 40A and lower die 40B). Therefore, the tip portions of the terminals 5d are pushed into the resin sheet 41.

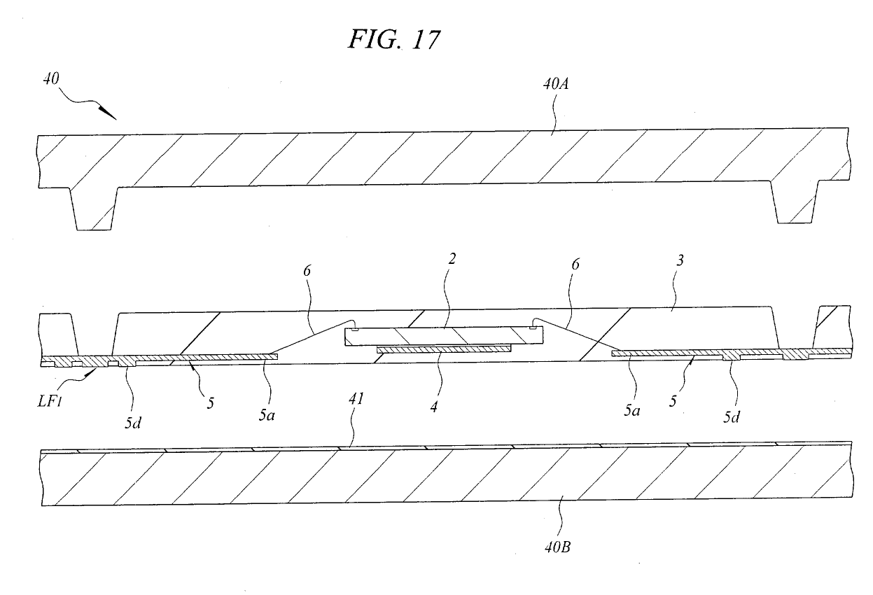

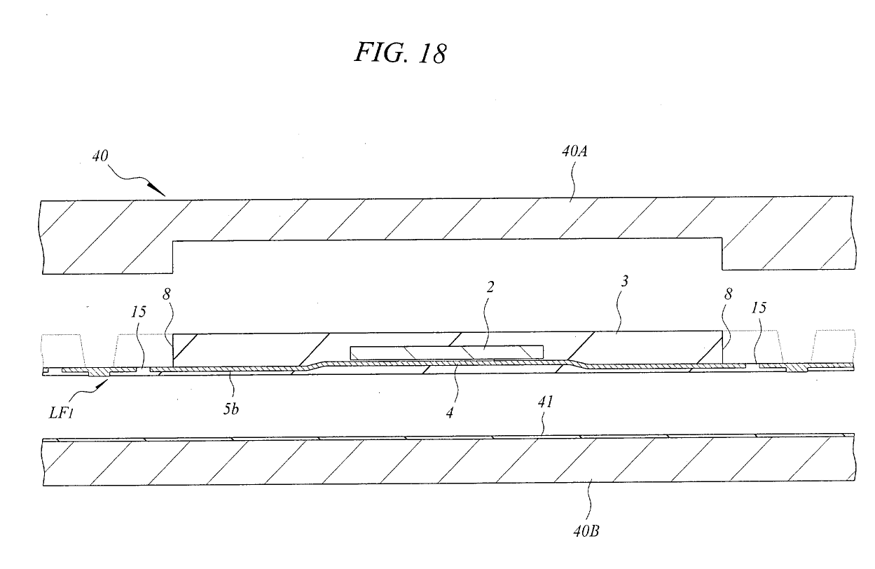

As a result, when the upper die 40A and the lower die 40B are detached from each other after injecting molten resin into the gap (cavity) between the upper and lower dies 40A and 40B to form the sealing body 3 as shown in FIG. 17, the tip portions of the terminals 5d pushed into the resin sheet 41 are protruded from the rear surface of the sealing body 3. At this time, as shown in FIG. 18, the notch sections 8 are formed in the two corner portions on the front surface of the sealing body 3, and the tip portions of the suspension leads 5b on which the reference marks 15 are formed are exposed in the notch sections 8.

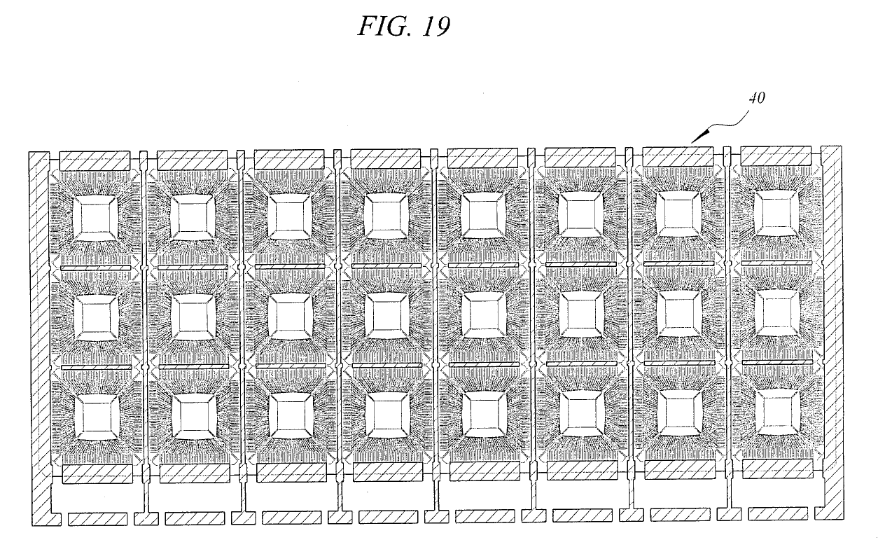

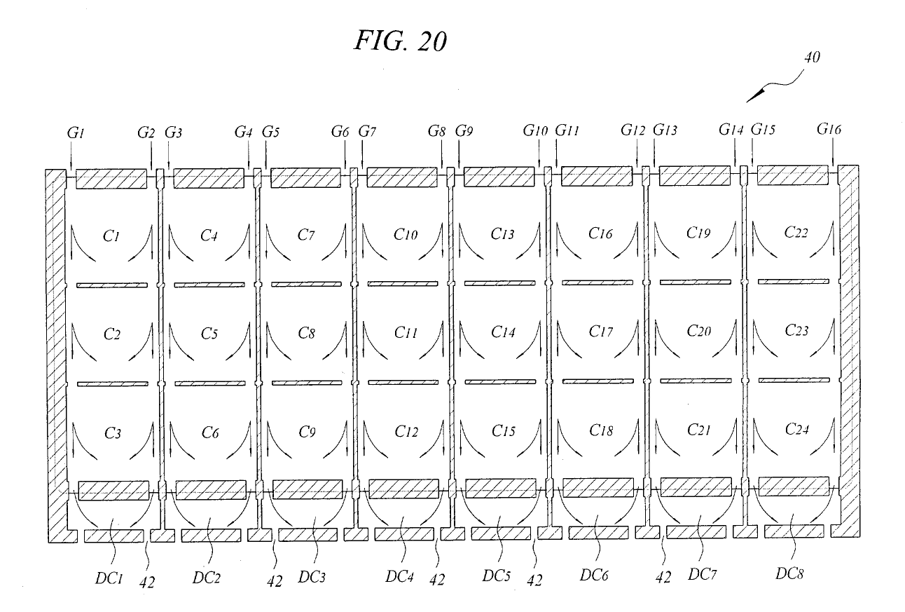

FIG. 19 is a plan view in which the part where the upper die 40A of the die 40 comes into contact with the lead frame LF₁ is marked with diagonal lines. Also, FIG. 20 is a plan view schematically showing the positions of gates of the molding die 40 and the flowing directions of the resin injected into the cavities.

As shown in FIG. 19, the upper die 40A comes into contact with only the outer frame portion of the lead frame LF₁ and the connection portions between the leads 5, and all of the other areas are effectively used as cavities in which the resin is injected.

In addition, as shown in FIG. 20, a plurality of gates G₁ to G₁₆ are provided on one side of the molding die 40, and the resin is injected through the gates G₁ and G₂ into the longitudinally arranged three cavities C₁ to C₃ on the left side of FIG. 20. The resin is injected through the gates G₃ and G₄ into the three cavities C₄ to C₆ adjacent to the cavities C₁ to C₃. Meanwhile, on the other side opposite to the gates G₁ to G₁₆, dummy cavities DC₁ to DC₈ and air vents 42 are provided. For example, when the resin is injected through the gates G₁ and G₂ into the cavities C₁ to C₃, the air in the cavities C₁ to C₃ is flown to the dummy cavity DC₁, which makes it possible to prevent the void created in the resin in the cavity C₃.

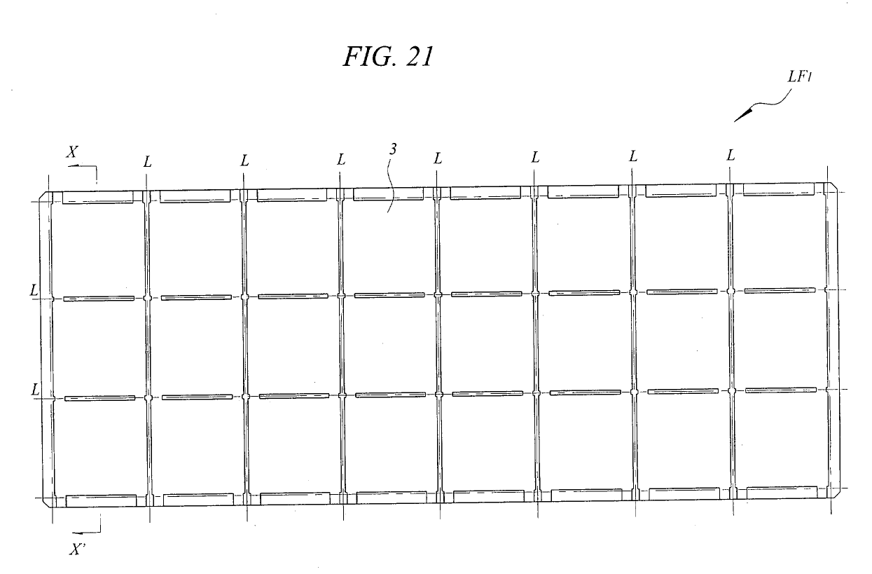

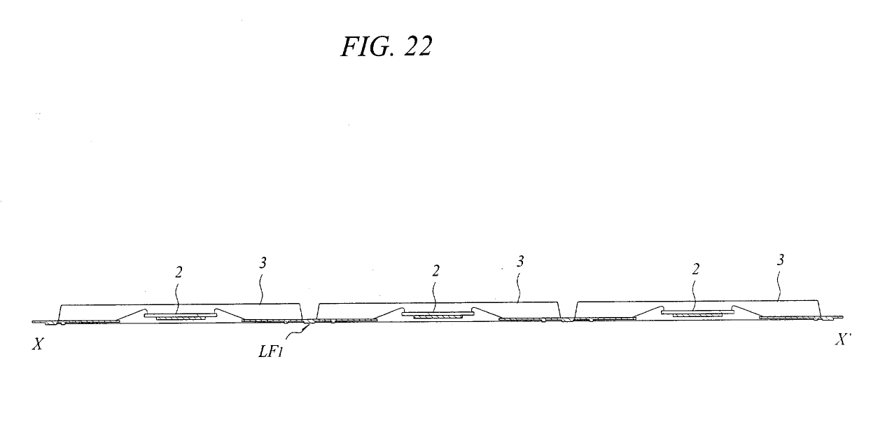

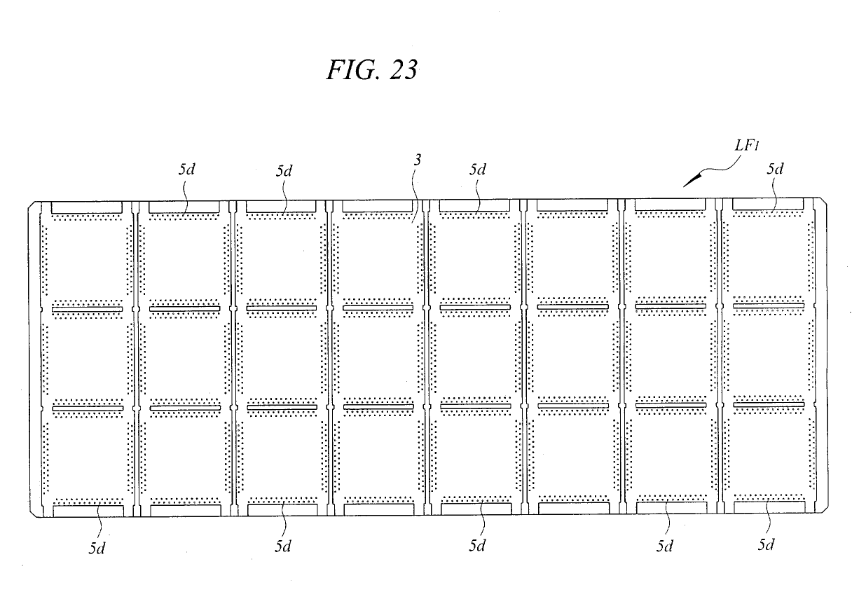

FIG. 21 is a plan view of the lead frame LF₁ detached from the die 40 after molding the sealing bodies 3 by injecting the resin into the cavities C₁ to C₁₈, FIG. 22 is a sectional view taken along the line X-X′ in FIG. 21, and FIG. 23 is a plan view showing a rear surface side of the lead frame LF₁.

Thereafter, the solder layers (9) are formed on the surfaces of the terminals 5d exposed on the rear surface of the lead frame LF₁, and then, marks such as product names are printed on the surface of the sealing body 3. Thereafter, the lead frame LF₁ and the part of the molding resin are cut along the dicing line L shown in FIG. 21. In this manner, the manufacture of the QFN 1 in the first embodiment shown in FIGS. 1 to 6 is completed.

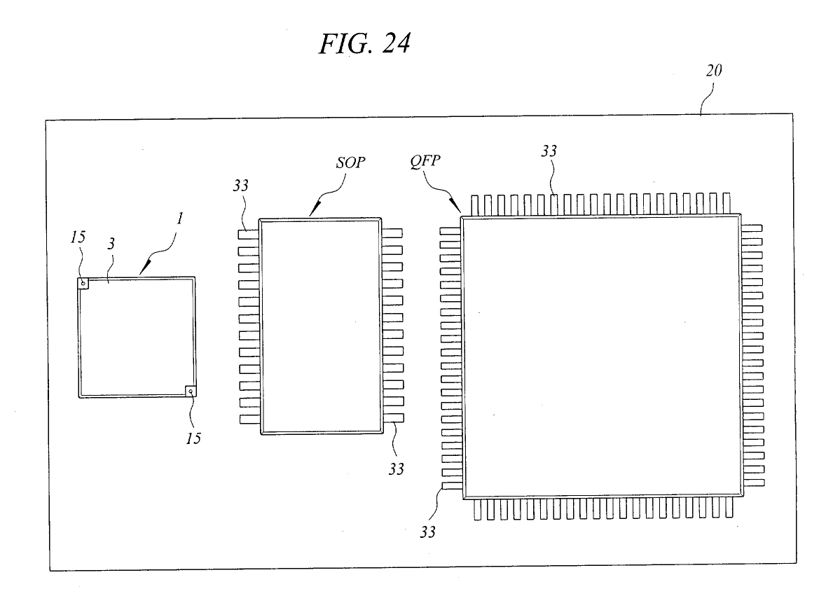

FIG. 24 is a plan view showing the state where the QFN 1 in this embodiment is mounted on the wiring board 20 together with other surface mounting type packages such as SOP (Small Outline Package) and QFP (Quad Flat Package). In the SOP and the QFP, since leads 33 are exposed from the side surfaces of the packages, it is possible to accurately align the leads 33 with the wiring board 20 by optically recognizing the positions of the leads 33 from above the wiring board 20.

Meanwhile, in the case of the QFN 1, the positions of the terminals 5d and the wiring board 20 are aligned by optically recognizing the positions of the reference marks 15 exposed in the two corner portions of the sealing body 3 from above the wiring board 20. Since the reference marks 15 are formed simultaneously with the formation of the die pad 4, the leads 5, the suspension leads 5b, and the terminals 5d as described above, there are no positional shift between the reference marks 15 and the terminals 5d. Therefore, by optically recognizing the positions of the reference marks 15 from above the wiring board 20, it is possible to accurately align the terminals 5d which cannot be recognized from above the wiring board 20 with the wiring board 20.

Since the reference marks 15 of the QFN 1 in this embodiment are simultaneously formed in the same process of forming the die pad 4, the leads 5, the suspension leads 5b, and the terminals 5d as described above, additional process dedicated to form the reference marks 15 is unnecessary.

In the QFN 1 in this embodiment, since the one end portions 5a of the leads 5 are extended to the positions near the die pad 4, it is possible to reduce the distance between the one end portions 5a and the semiconductor chip 2, and consequently to reduce the length of the Au wires 6 to connect them. In addition, since the length of the one end portions 5a of the leads 5 is almost equal even if the terminals 5d are arranged in a zigzag pattern, the tips of the one end portions 5a form one line for each of the sides of the semiconductor chip 2. Therefore, the length of the Au wires 6 which connect the one end portions 5a of the leads 5 and the semiconductor chip 2 can be made almost uniform, and also, the loop shape of the Au wires 6 can be made almost uniform.

Consequently, it is possible to prevent such defects that the adjoining gold wires 6 are short circuited and that the adjoining gold wires 6 are crossed to each other particularly in the vicinity of the four corners of the semiconductor die 2. Therefore, the workability in the wire bonding process can be improved. In addition, since it is possible to reduce the pitch between the adjacent Au wires 6, the number of pins used in the QFN 1 can be increased.

Also, since one end portions 5a of the leads 5 are extended to the positions near the die pad 4, the length between the terminal 5d and the one end portion 5a of the lead 5 is increased. Therefore, since moisture getting into the sealing body 3 through the terminal 5d exposed to the outside of the sealing body 3 cannot easily reach the semiconductor chip 2, corrosion of the bonding pad 7 due to the moisture can be prevented. As a result, the reliability of the QFN 1 is improved.

Also, since the one end portions 5a of the leads 5 are extended to the positions near the die pad 4, the increase in length of the Au wires 6 is extremely small even if the semiconductor die 2 is shrunk (for example, even if the semiconductor die 2 is shrunk from 4 mm square to 3 mm square, the increase in length of the Au wires 6 is about 0.7 mm on average). Therefore, it is possible to prevent the deterioration of the workability in the wire bonding process caused from the shrinkage of the semiconductor chip 2.

(Second Embodiment)

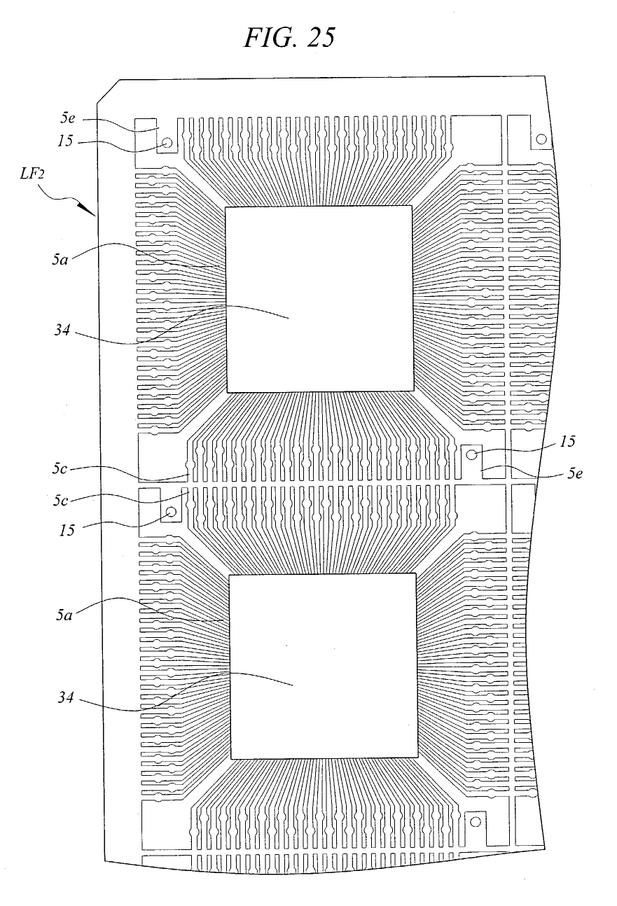

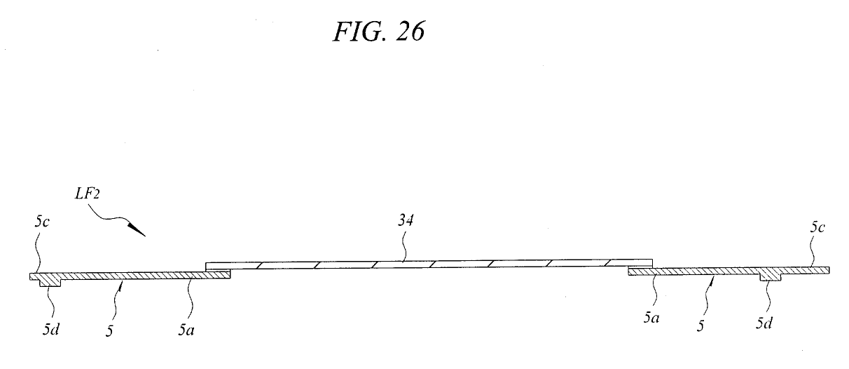

The QFN manufactured by using the lead frame LF₁ with a small-tab structure has been described in the first embodiment. However, as shown in FIGS. 25 and 26, it is also possible to manufacture the QFN by using a lead frame LF₂ in which a chip support 34 made of insulating film is adhered onto one end portions 5a of the leads 5.

Also, the die pad 4 is supported by four suspension leads 5b in the lead frame LF₁ in the first embodiment. However, since the chip support 34 is supported by the one end portions 5a of the leads 5 in the lead frame LF₂ in the second embodiment, there are no suspension leads 5b. Therefore, in the second embodiment, aligning leads 5e which are not electrically connected to the semiconductor chip 2 are provided as shown in FIG. 25, and the reference marks 15 are formed on the parts of the aligning leads 5e.

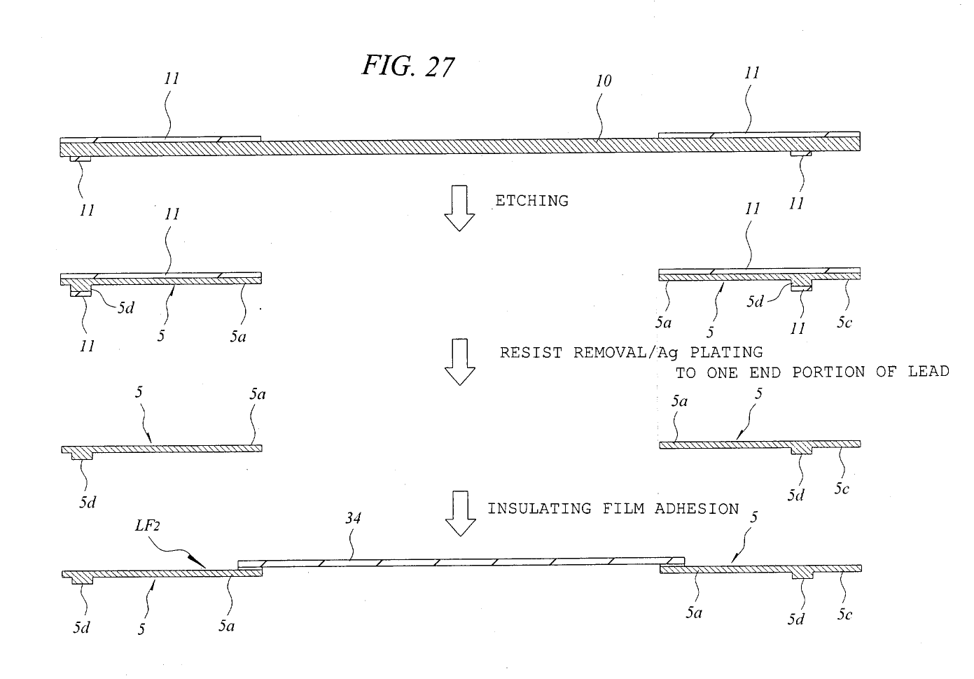

The lead frame LF₂ used in this embodiment can be manufactured through the process similar to that of the lead frame LF₁ in the first embodiment. More specifically, a metal plate 10 with a thickness of about 150 μm as shown in FIG. 27 is prepared, and one surface of the parts of the metal plate 10 where the leads 5 are to be formed is covered with a photoresist film 11. Also, both surfaces of the parts of the metal plate 10 where the external connection terminals 5d are to be formed are covered with the photoresist film 11. Though not shown, the photoresist film 11 is formed on one surface of the parts where the aligning leads 5e are to be formed, and no photoresist film 11 is formed on both surfaces of only the parts where the reference marks 15 are to be formed.

Then, the metal plate 10 is half-etched in accordance with the method described in the first embodiment, thereby simultaneously forming the leads 5 and the aligning leads 5e with a thickness of about 75 μm and the terminals 5d with a thickness of about 150 μm. Thereafter, Ag plating is performed to the surfaces of the one end portions 5a of the leads 5, and then, the chip support 34 is adhered to the one surfaces of the one end portions 5a. Note that it is also possible to form the chip support 34 with a conductive material such as a thin metal plate instead of the insulating film. In this case, it is preferable to adhere the leads 5 and the chip support 34 with insulating adhesive in order to prevent the short circuit of the leads 5. In addition, it is also possible to form the chip support 34 by using a sheet obtained by coating the surface of metal foil with insulating resin.

Also in the case of using the lead frame LF₂ as described above, the thickness of the leads 5 can be reduced to about half of that of the metal plate 10 by performing the half etching to the one surface of the parts of the metal plate 10 with using the photoresist film 11 as a mask. Therefore, it is possible to accurately form the leads 5 so that the pitch of the one end portions 5a of the leads 5 is extremely short (for example, 0.18 mm to 0.2 mm pitch). Also, by masking both surfaces of the parts of the metal plate 10 with the photoresist film 11, it is possible to form the convex terminals 5b simultaneously with the leads 5.

Since the chip support 34 is supported by leads 5 in the lead frame LF₂ described above, the distance between the one end portions 5a of the leads 5 and the semiconductor chip 2 becomes short, and it is possible to further reduce the length of the Au wires 6. Furthermore, since it is possible to support the chip support 34 more securely than the case where the die pad 4 is supported by the four suspension leads 5b, the deformation of the chip support 34 caused when injecting the molten resin into the die in the molding process can be reduced, and thus, the short circuit between the Au wires 6 can be prevented.

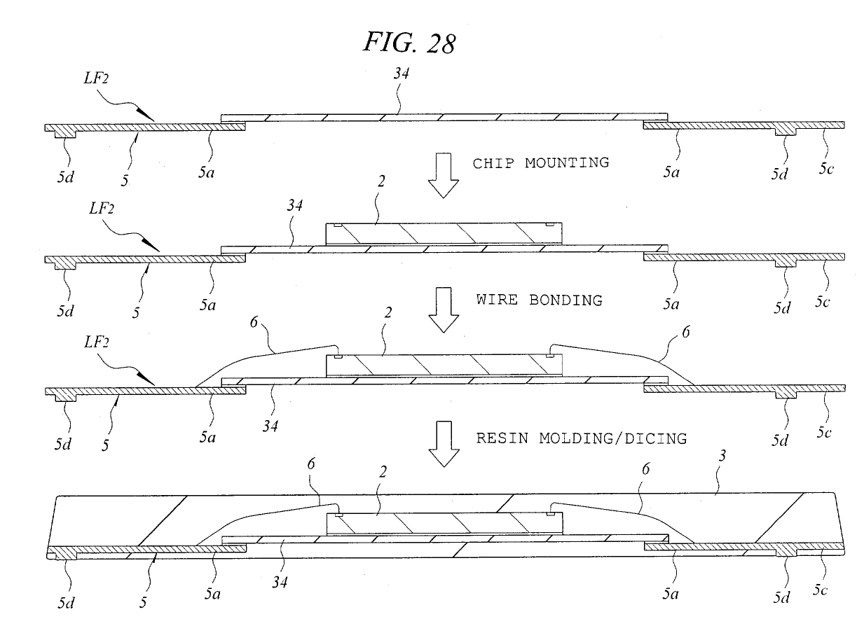

As shown in FIG. 28, the manufacturing method of the QFN 1 using the lead frame LF₂ is almost identical to that described in the first embodiment.

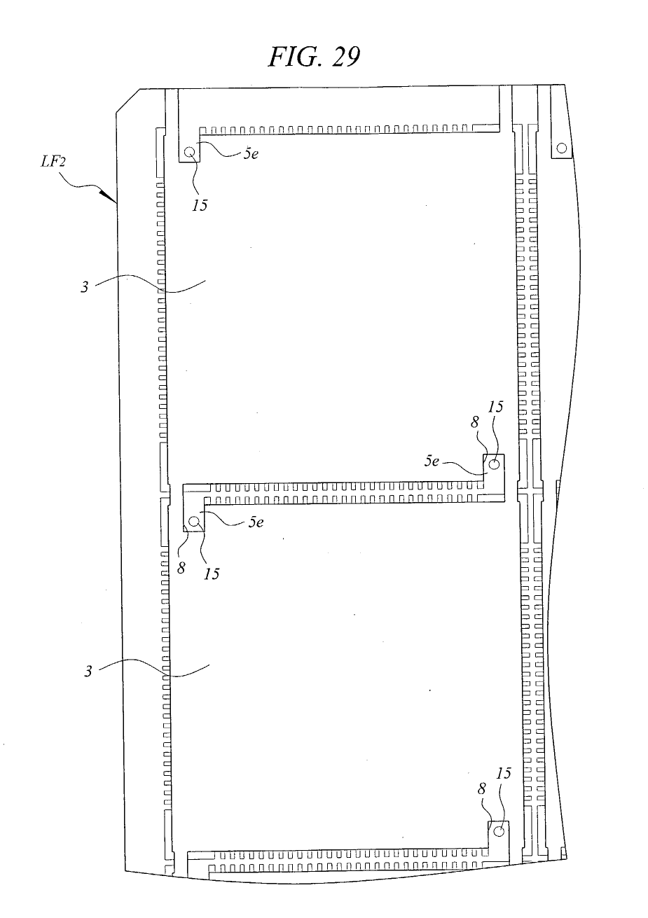

FIG. 29 is a plan view showing a part of the lead frame LF₂ after the finish of the resin molding process. As shown in FIG. 29, the notch sections 8 are provided in each of the two diagonal corner portions on the front surface of the sealing body 3, and the aligning leads 5e in which the reference marks 15 are formed are exposed thereon. Therefore, also in the QFN 1 in this embodiment, it is possible to accurately align the terminals 5d which cannot be recognized from the front surface side of the sealing body 3 with the wiring board by optically recognizing the positions of the reference marks 15 from above.

(Third Embodiment)

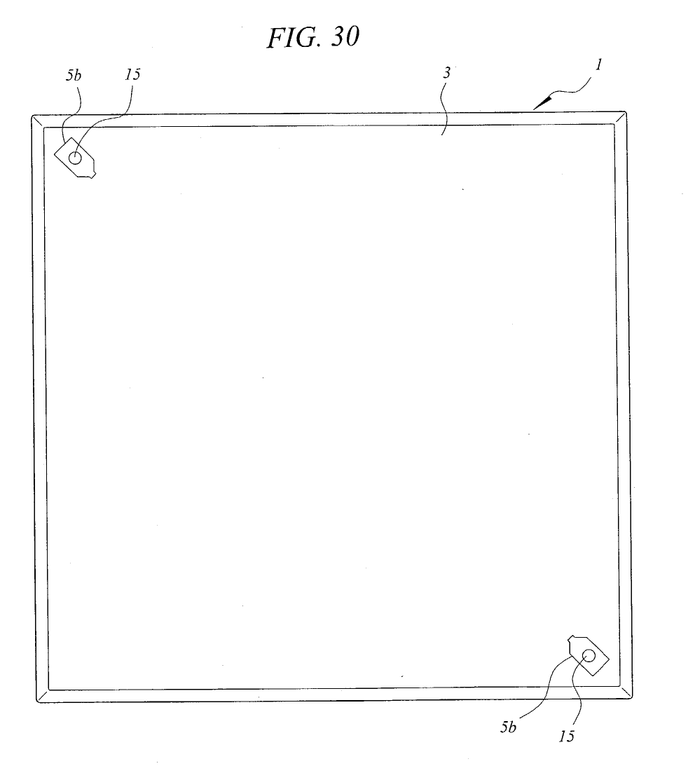

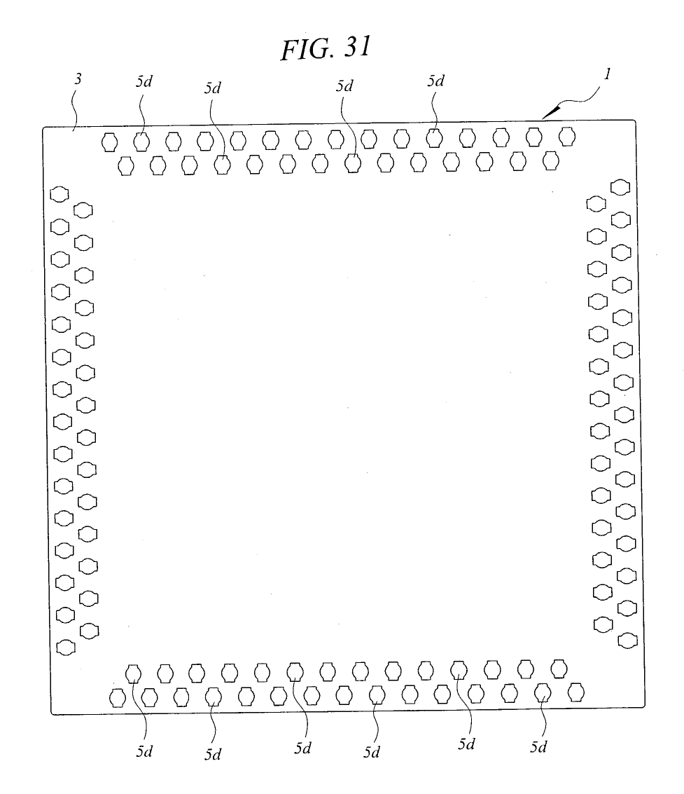

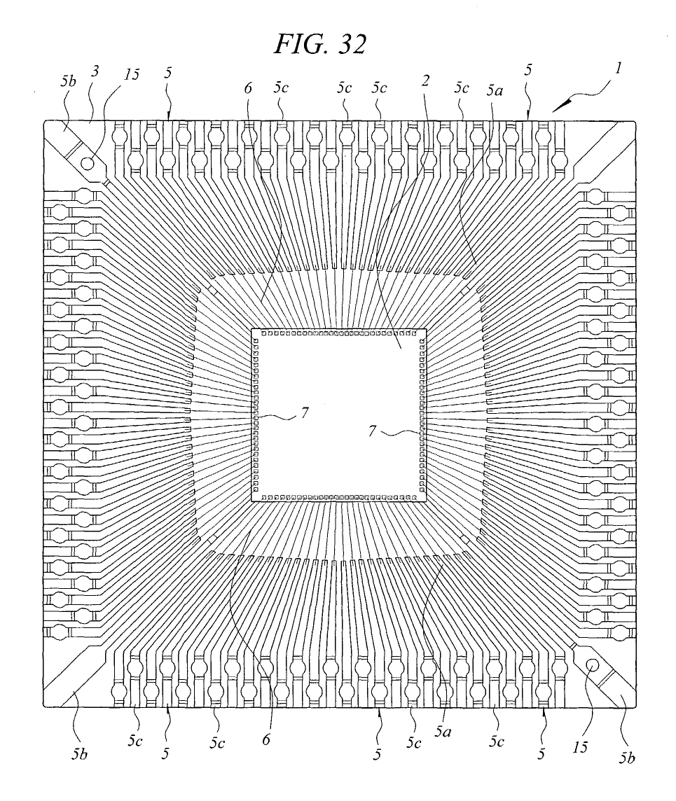

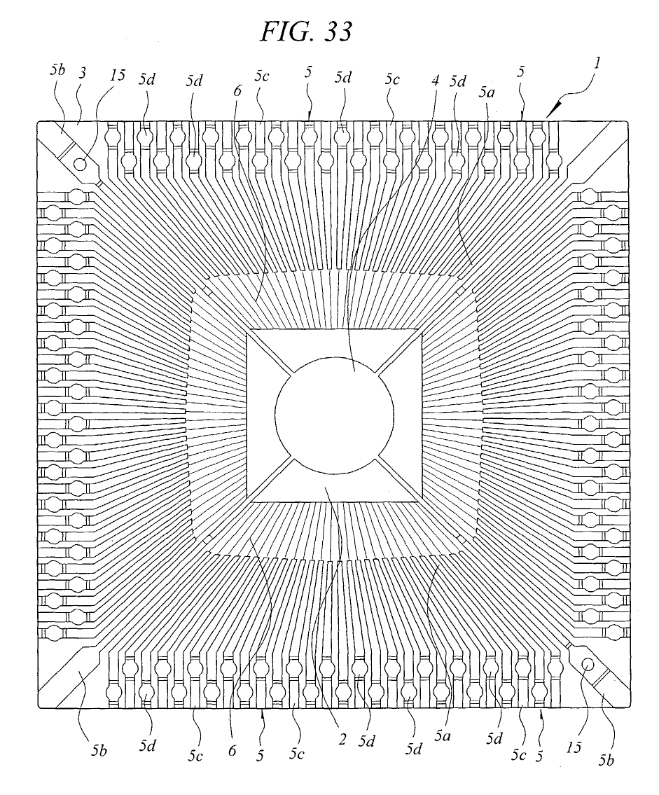

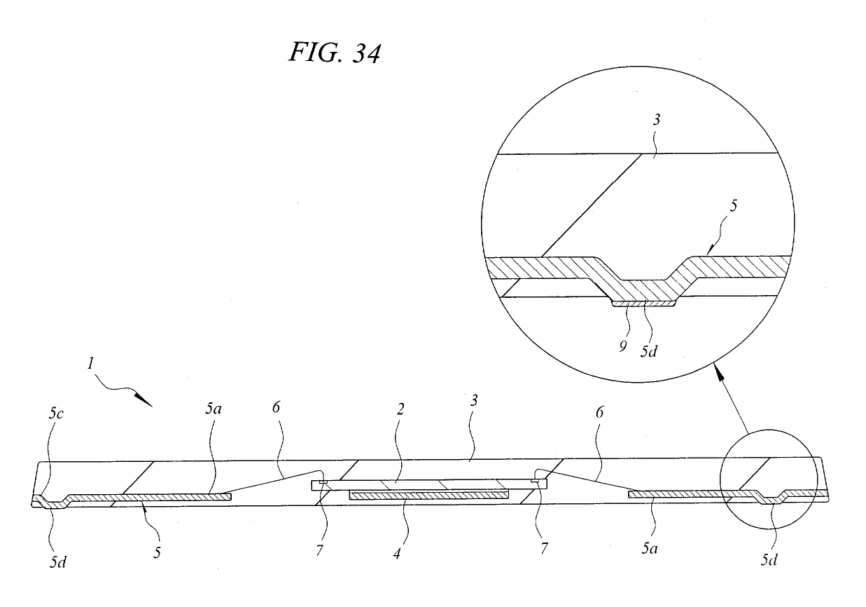

FIG. 30 is a plan view showing an outward appearance (front surface side) of a QFN in this embodiment, FIG. 31 is a plan view showing the outward appearance (rear surface side) of the QFN, FIG. 32 is a plan view showing an inner structure (front surface side) of the QFN, FIG. 33 is a plan view showing the inner structure (rear surface side) of the QFN, and FIGS. 34 to 36 are sectional views of the QFN.

The QFN 1 in this embodiment has a structure in which one semiconductor chip 2 is sealed in the sealing body 3 made of synthetic resin, and the outside dimensions of the sealing body 3 are, for example, length 12 mm, width 12 mm, and height 0.5 mm. The outside dimensions of the semiconductor chip 2 mounted on the die pad 4 and disposed in the center portion of the sealing body 3 are, for example, length 4 mm, width 4 mm, and height 0.14 mm. The die pad 4 has the small-tab structure and is supported by the four suspension leads 5b. The one end portions (on the side near the semiconductor chip 2) 5a of the leads 5 arranged around the die pad 4 are electrically connected to the bonding pads 7 on the main surface of the semiconductor chip 2 via the Au wires 6, and the other end portions 5c are terminated at the side surfaces of the sealing body 3. The one end portions 5a of the leads 5 are respectively extended to the positions near the die pad 4 in order to reduce the distance between the one end portions 5a and the semiconductor chip 2, and the pitch of the tips of the one end portions 5a is designed to be smaller than that of the other end portions 5c.

As shown in FIG. 30, each part of the two suspension leads 5b is exposed in the vicinity of the two diagonal corner portions on the surface of the sealing body 3. The part of the suspension lead 5b exposed on the surface of the sealing body 3 is wider than the part of the suspension lead 5b inside the sealing body 3. The reference mark 15 is provided in the part of the suspension lead 5b exposed on the surface of the sealing body 3 so that the reference marks 15 can be optically recognized from the front surface side of the sealing body 3 when mounting the QFN 1 to the wiring board.

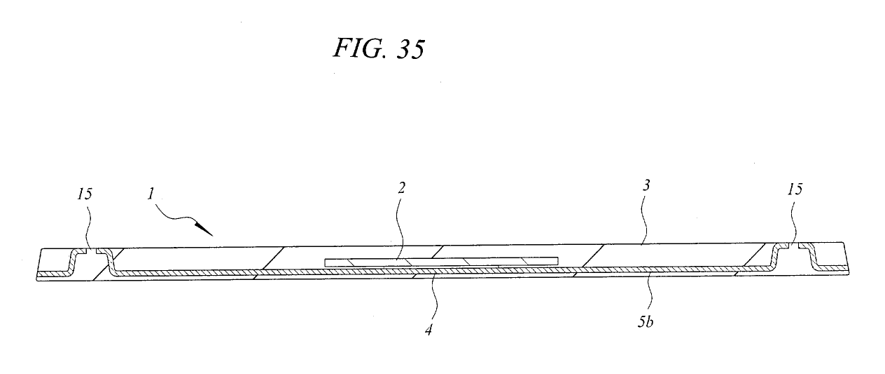

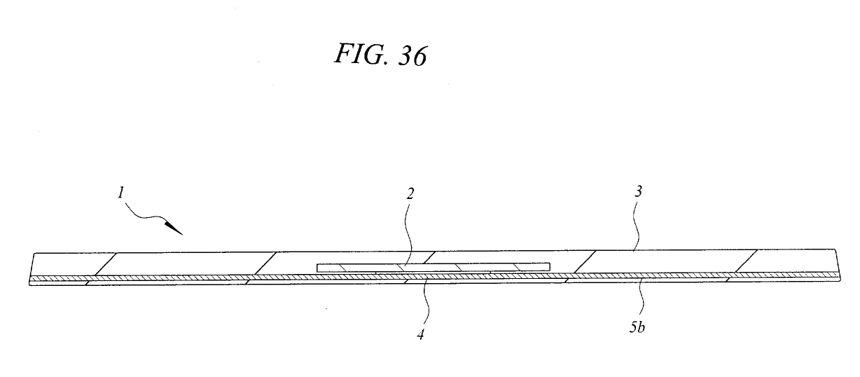

As shown in FIG. 35, the two suspension leads 5b are bent upward so that the part exposed on the surface of the sealing body 3, that is, the part in which the reference marks 15 are provided comes level with the surface of the sealing body 3. Meanwhile, as shown in FIG. 36, the other two suspension leads 5b in which the reference marks 15 are not provided are not bent upward.

As shown in FIGS. 31 and 34, a plurality of (for example, 116) external connection terminals 5b formed by bending the parts of the plurality of leads 5 downward are provided in two lines in a zigzag pattern along each side on the rear surface of the sealing body 3. These terminals 5d are protruded from the rear surface of the sealing body 3 to the outside, and the solder layers 9 are formed on the surfaces thereof by the printing method or the plating method. The degree of bending of the leads 5 and the thickness of the solder layer 9 are determined so that the height of the terminal 5d including that of the solder layer 9, that is, the amount of protrusion (standoff amount) from the rear surface of the sealing body 3 is at least 50 μm or longer. The width of each terminal 5d is made wider than that of the lead 5 in order to sufficiently obtain the mounting area with the wiring board.

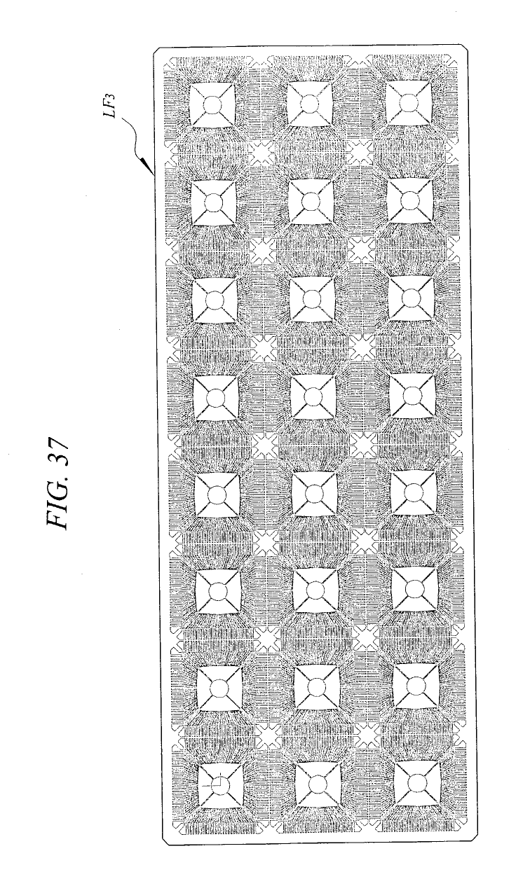

FIG. 37 is a plan view of a lead frame LF₃ used in the manufacture of the QFN 1 in this embodiment. The lead frame LF₃ is composed of a metal plate made of Cu, Cu alloy, or Fe—Ni alloy with a thickness of about 100 to 150 μm, and above-described patterns such as die pads 4, leads 5, and suspension leads 5b are consecutively formed laterally and longitudinally. More specifically, the lead frame LF₃ has a multiple structure in which a plurality of (for example, 24) semiconductor chips 2 can be mounted.

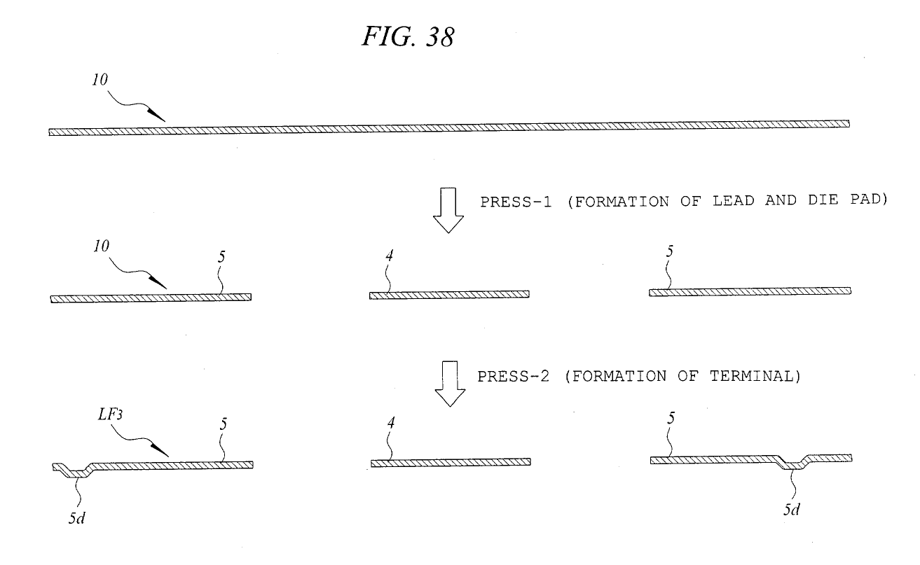

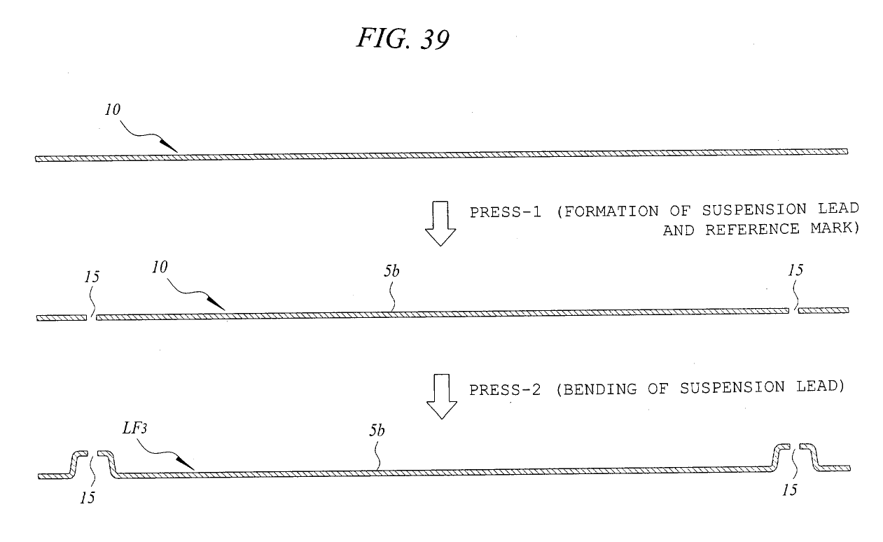

The lead frame LF₃ is manufactured in the following manner. First, as shown in FIG. 38, the metal plate 10 is pressed and punched to form such patterns as the leads 5, the suspension leads 5b, the die pads 4, and the reference marks 15. Subsequently, intermediate parts of the leads 5 are pressed and bent downward to form the terminals 5d. Also in this case, the intermediate parts of the suspension leads 5b (portions where the reference marks 15 are formed) are pressed and bent upward as shown in FIG. 39.

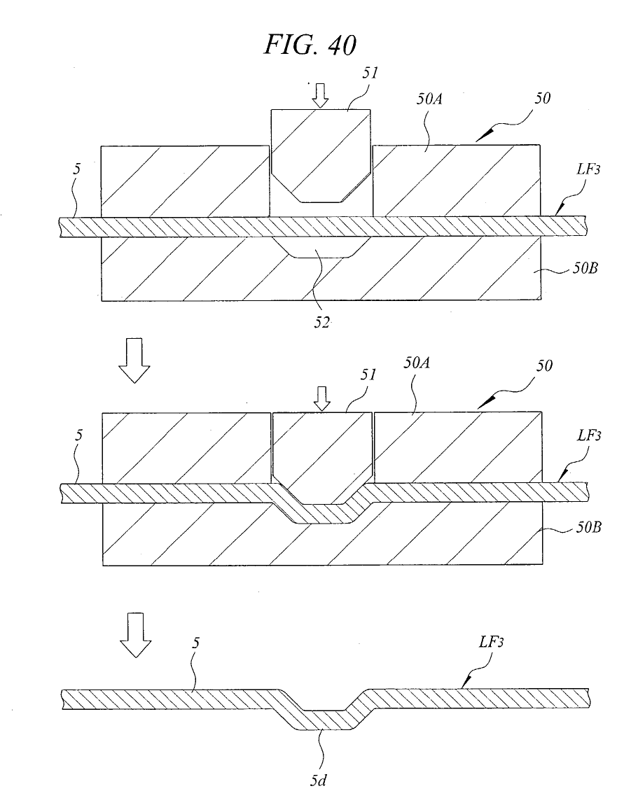

The terminals 5d are formed in the following manner. That is, the metal plate 10 is sandwiched between the upper die 50A and the lower die 50B of the press die 50 as shown in FIG. 40. In this state, when a punch 51 provided in the upper die 50A is pressed into a die 52 provided in the lower die 50B, the intermediate part of each lead 5 is plastically deformed and bent downward, and thus, the terminals 5d are formed. Though not shown, when bending the suspension leads 5b upward, the punch 51 provided in the lower die 50B is pressed into the die 52 provided in the upper die 50A. Thereafter, Ag plating layers are formed on one surfaces of the one end portions 5a of the leads 5 (areas where the Au wires are bonded) by the electroplating method, thereby finishing the manufacture of the lead frame LF₃.

In this embodiment as described above, since such patterns as the leads 5, the suspension leads 5b, the die pads 4, the terminals 5d, and the reference marks 15 are formed by pressing and shearing the metal plate 10, the manufacturing process of the lead frame LF₃ is simplified in comparison with the case where these patterns are formed by the etching, and thus, the manufacturing cost thereof can be reduced.

The method of mounting the semiconductor chip 2 to the die pad 4 of the lead frame LF₃, connecting the bonding pads 7 of the semiconductor chip 2 and the one end portions 5a of the leads 5 by the Au wires, placing the lead frame LF₃ to the molding die, and then, sealing the semiconductor chip 2 is the same as that in the first embodiment.

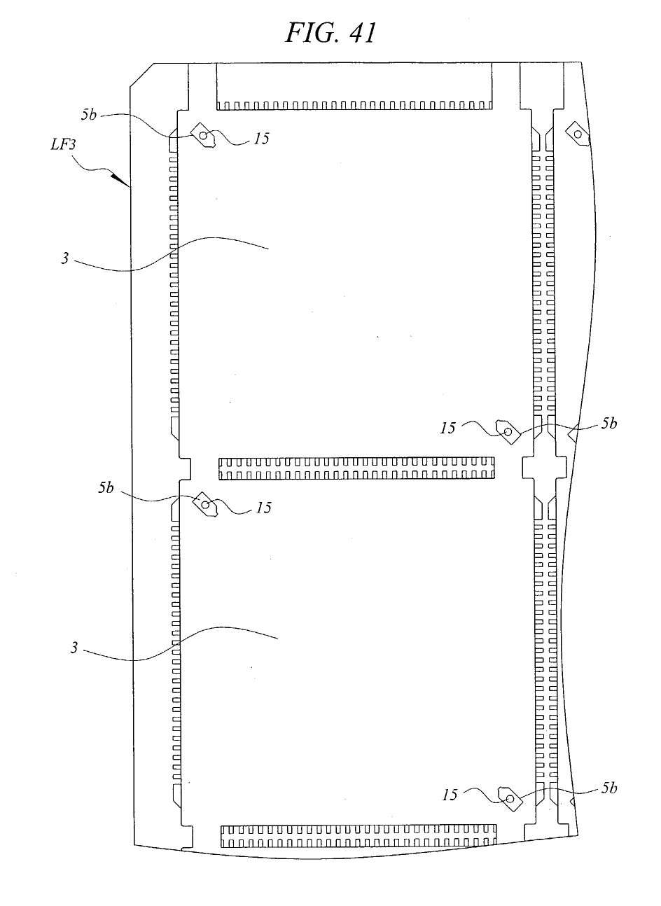

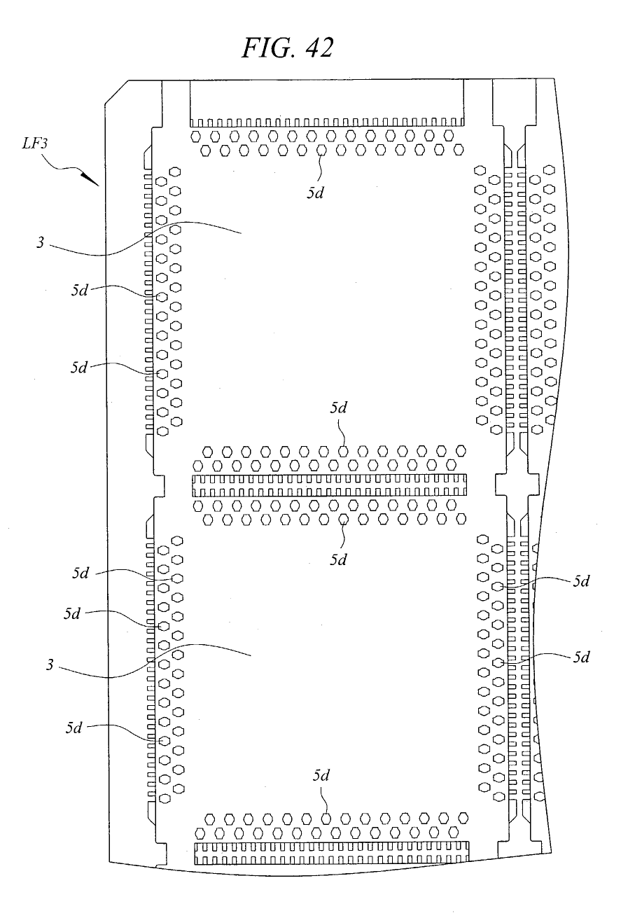

FIG. 41 is a plan view showing the principal part of the front surface side of the lead frame LF₃ detached from the molding die, and FIG. 42 is a plan view showing the principal part of the rear surface side of the lead frame LF₃. As shown in FIGS. 41 and 42, when the lead frame LF₃ is detached from the molding die, each part of the two suspension leads 5b (portions where the reference marks 15 are formed) are exposed on the front surface of the sealing body 3, and the plurality of terminals 5d are exposed on the rear surface of the sealing body 3.

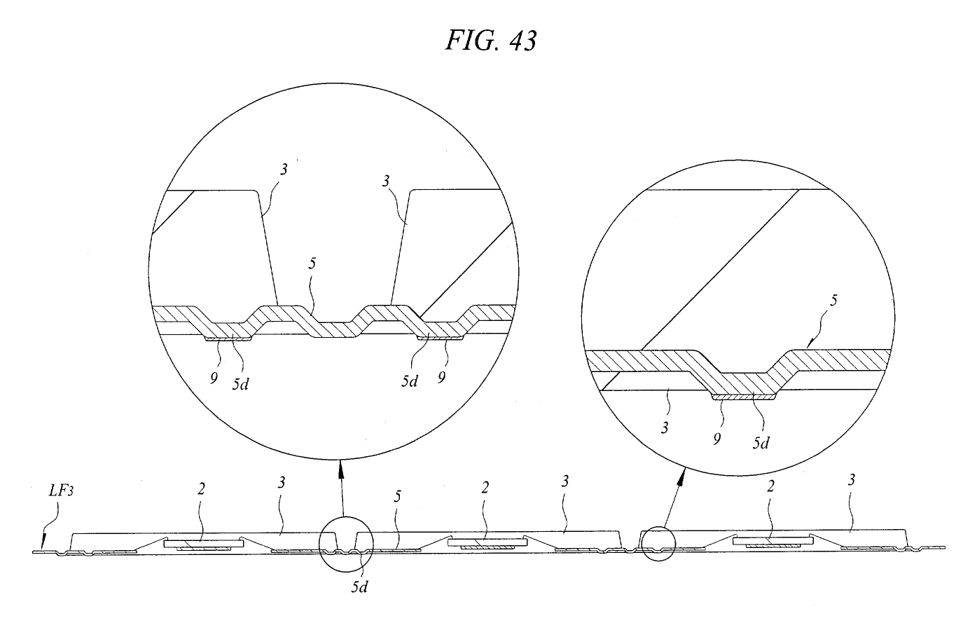

Next, as shown in FIG. 43, the solder layers 9 are formed on the surfaces of the terminals 5d exposed from the rear surface of the sealing body 3. The electroplating method or the printing method is used to form the solder layer 9. However, the solder printing method is more preferable because it can form a thick solder layer 9 in a short time. When using the solder printing method, the solder with a thickness of about 30 to 100 μm is printed by the screen printing method using a metal mask, and subsequently, the lead frame LF₃ is heated in a heating furnace to reflow the solder.

Thereafter, though not shown, marks such as product names are printed on the surface of the sealing body 3, and then, the connection portions between the leads 5 exposed to the outside of the sealing body 3 are cut by the dicing or the die punching to divide the lead frame LF₃ for singularizing the sealing bodies 3. In this manner, the manufacture of the QFN 1 in this embodiment shown in FIGS. 30 to 36 is completed.

The QFN 1 in this embodiment is mounted on the wiring board by soldering the plurality of terminals 5d protruded from the rear surface of the sealing body 3 to the outside and the electrodes (footprints) of the wiring board. In this process, the terminals 5d and the wiring board are aligned based on the optical recognition of the positions of the reference marks 15 exposed in the two corner portions of the sealing body 3 from above the wiring board. Since the reference marks 15 are formed simultaneously with the formation of the die pads 4, the leads 5, the suspension leads 5b, and the terminals 5d, there are no positional shift between the reference marks 15 and the terminals 5d. Therefore, by optically recognizing the positions of the reference marks 15 from above the wiring board, it is possible to accurately align the terminals 5d which cannot be recognized from above the wiring board 20 with the wiring board 20.

Also, according to the third embodiment, since such patterns as the leads 5, the suspension leads 5b, the die pads 4, the terminals 5d, and the reference marks 15 are formed by the press, the manufacturing process of the lead frame LF₃ can be simplified in comparison with the case where these patterns are formed by the etching. Consequently, since it is possible to reduce the manufacturing cost of the lead frame LF₃, it is possible to reduce the manufacturing cost of the QFN 1 using the lead frame LF₃.

Various shapes such as a square and an oval are available as the shape of the terminal 5d. Further, in the case of the QFN with relatively small number of terminals, the width of the lead 5 is large in comparison with the case of the QFN with large number of terminals. Therefore, it is also possible to make the width of the terminal 5d equal to that of the lead 5.

In the foregoing, the invention made by the inventors of the present invention has been concretely described based on the embodiments. However, it is needless to say that the present invention is not limited to the foregoing embodiments and various modifications and alterations can be made within the scope of the present invention.

The advantages achieved by the typical ones of the inventions disclosed in this application will be briefly described as follows.

Since the parts of the leads are exposed on the upper surface of the sealing body that constitutes the QFN and the reference marks are formed in the parts, it is possible to accurately align the external connection terminals arranged on the rear surface of the sealing body with the wiring board by optically recognizing the positions of the reference marks from above the wiring board when mounting the QFN on the wiring board.

What is claimed is:

1. A semiconductor device, comprising: a semiconductor chip; a die pad on which the semiconductor chip is mounted; suspension leads to support the die pad; a plurality of leads arranged around the die pad; a plurality of wires to electrically connect the semiconductor chip to the plurality of leads; and a sealing body for sealing the semiconductor chip, the die pad, the suspension leads, the plurality of leads, and the plurality of wires,
wherein an external connection terminal protruded from a rear surface of the sealing body to the outside is selectively provided on each of the plurality of leads;
wherein a part of the suspension leads is exposed from an upper surface of the sealing body to the outside; and
wherein a reference mark used for the alignment between the external connection terminals and a wiring board is formed on the part of the suspension leads exposed from the upper surface of the sealing body to the outside.

2. The semiconductor device according to claim 1,
wherein the part of the suspension leads is exposed to the outside of the sealing body by providing a notch section in a part of the upper surface of the sealing body.

3. The semiconductor device according to claim 1,
wherein the part of the suspension leads is exposed to the outside of the sealing body by bending the part of the suspension leads upward.

4. The semiconductor device according to claim 1,
wherein the external connection terminals are the parts of the plurality of leads bent downward so as to be exposed from the rear surface of the sealing body to the outside.

5. The semiconductor device according to claim 1,
wherein the external connection terminals are arranged in two lines in a zigzag pattern along each side of the rear surface of the sealing body.

6. A semiconductor device, comprising:
a semiconductor chip; a die pad on which the semiconductor chip is mounted; a plurality of leads arranged around the die pad; a plurality of wires to electrically connect the semiconductor chip to the leads; and a sealing body for sealing the semiconductor chip, the die pad, the plurality of leads, and the plurality of wires,
wherein an external connection terminal protruded from a rear surface of the sealing body to the outside is selectively provided on each of the plurality of leads;
wherein a part of the plurality of leads is exposed from an upper surface of the sealing body to the outside; and
wherein a reference mark used for the alignment between the external connection terminals and a wiring board is formed on the part of the leads exposed from the upper surface of the sealing body to the outside.

7. The semiconductor device according to claim 6,
wherein the lead exposed from the upper surface of the sealing body to the outside is not electrically connected to the semiconductor chip.

8. The semiconductor device according to claim 6,
wherein the part of the leads is exposed to the outside of the sealing body by providing a notch section in a part of the upper surface of the sealing body.

9. A semiconductor device, comprising: a semiconductor chip; a chip support in a sheet form on which the semiconductor chip is mounted; a plurality of leads arranged around the semiconductor chip; a plurality of wires to electrically connect the semiconductor chip to the leads; and a sealing body for sealing the semiconductor chip, the chip support, the plurality of leads, and the plurality of wires,
wherein an external connection terminal protruded from a rear surface of the sealing body to the outside is selectively provided on each of the plurality of leads;
wherein a part of the plurality of leads is exposed from an upper surface of the sealing body to the outside; and
wherein a reference mark used for the alignment between the external connection terminals and a wiring board is formed on the part of the leads exposed from the upper surface of the sealing body to the outside.

10. The semiconductor device according to claim 9,
wherein the lead exposed from the upper surface of the sealing body to the outside is not electrically connected to the semiconductor chip.

11. The semiconductor device according to claim 9,
wherein the chip support is supported by the plurality of leads.

12. A method of manufacturing a semiconductor device, which comprises: a semiconductor chip; a die pad on which the semiconductor chip is mounted; suspension leads to support the die pad; a plurality of leads arranged around the semiconductor chip; a plurality of wires to electrically connect the semiconductor chip to the leads; and a sealing body for sealing the semiconductor chip, the die pad, the plurality of leads, and the plurality of wires, the method comprising the steps of:
(a) press-forming a metal plate to prepare a lead frame in which patterns including the die pads, the suspension leads, and the plurality of leads are repeatedly formed;
(b) bending a part of the respective leads formed in the lead frame in the direction vertical to one surface of the lead frame, thereby forming external connection terminals;
(c) bending a part of the suspension leads in the direction reverse to that of the protrusion of the external connection terminals;
(d) forming a reference mark used for the alignment between the external connection terminals and a wiring board in the bent part of the suspension leads;
(e) mounting the semiconductor chip on each of the plurality of die pads formed in the lead frame, and connecting the semiconductor chip to a part of the leads by the wires;
(f) preparing a molding die with an upper die and a lower die, and covering a surface of the lower die with a resin sheet, then placing the lead frame on the resin sheet to contact the external connection terminals formed on one surfaces of the leads to the resin sheet;
(g) sandwiching the resin sheet and the lead frame with the upper die and the lower die, thereby pushing tip portions of the external connection terminals into the resin sheet;
(h) injecting resin into spaces between the upper and lower dies, thereby sealing the semiconductor chips, the die pads, the suspension leads, the leads, and the wires to form a plurality of sealing bodies in which the external connection terminals are protruded from the rear surface to the outside and the bent parts of the suspension leads are exposed on the upper surface; and
(i) detaching the lead frame on which the plurality of sealing bodies are formed from the molding die, then cutting the lead frame, thereby singularizing the plurality of sealing bodies.

13. The method of manufacturing a semiconductor device according to claim 12,
wherein the steps (b), (c), and (d) are simultaneously conducted.

14. A method of manufacturing a semiconductor device, which comprises: a semiconductor chip; a die pad on which the semiconductor chip is mounted; suspension leads to support the die pad; a plurality of leads arranged around the semiconductor chip; a plurality of wires to electrically connect the semiconductor chip to the plurality of leads; and a sealing body for sealing the semiconductor chip, the die pad, the plurality of leads, and the plurality of wires, the method comprising the steps of:
(a) etching a metal plate to prepare a lead frame in which patterns including the die pads, the suspension leads, and the plurality of leads are repeatedly formed;
(b) forming an external connection terminal on each part of the plurality of leads formed in the lead frame;
(c) forming a reference mark used in the alignment between the external connection terminals and a wiring board on a part of the suspension leads;
(d) mounting a semiconductor chip on each of the plurality of die pads formed in the lead frame, and then, connecting the semiconductor chip to the parts of the leads;
(e) preparing a molding die with an upper die and a lower die, and covering a surface of the lower die with a resin sheet, then placing the lead frame on the resin sheet to contact the external connection terminals formed on the respective parts of the plurality of leads to the resin sheet;
(f) sandwiching the resin sheet and the lead frame with the upper die and the lower die, thereby pushing tip portions of the external connection terminals into the resin sheet;
(g) injecting resin into spaces between the upper and lower dies, thereby sealing the semiconductor chips, the die pads, the suspension leads, the plurality of leads, and the plurality of wires to form a plurality of sealing bodies in which the external connection terminals are protruded from the rear surface to the outside and the part of the suspension leads in which the reference mark is formed is exposed on the upper surface; and
(h) detaching the lead frame on which the plurality of sealing bodies are formed from the molding die, then cutting the lead frame, thereby singularizing the plurality of sealing bodies.

15. The method of manufacturing a semiconductor device according to claim 14,
wherein the steps (a), (b), and (c) are simultaneously conducted.

16. A method of manufacturing a semiconductor device, which comprises: a semiconductor chip; a chip support in a sheet form on which the semiconductor chip is mounted; a plurality of leads arranged around the semiconductor chip; a plurality of wires to electrically connect the semiconductor chip to the leads; and a sealing body for sealing the semiconductor chip, the chip support, the plurality of leads, and the plurality of wires, the method comprising the steps of:
(a) press-forming or etching a metal plate to prepare a lead frame in which patterns including the plurality of leads are formed consecutively, an external connection terminal protruding in the direction vertical to one surface of the plurality of leads is formed on each surface of the plurality of leads, and a reference mark used in the alignment between the external connection terminals and a wiring board is formed on a part of the plurality of leads;
(b) attaching the chip supports in a sheet form supported by the plurality of leads to a plurality of semiconductor chip mounting areas of the lead frame;
(c) mounting the semiconductor chip to each of the plurality of chip supports, and connecting the semiconductor chip to the part of the plurality of leads by the wires;
(d) preparing a molding die with an upper die and a lower die, and covering a surface of the lower die with a resin sheet, then placing the lead frame on the resin sheet to contact the external connection terminals formed on one surfaces of the plurality of leads to the resin sheet;
(e) sandwiching the resin sheet and the lead frame with the upper die and the lower die, thereby pushing tip portions of the external connection terminals into the resin sheet;
(f) injecting resin into spaces between the upper and lower dies, thereby sealing the semiconductor chips, the chip supports, the leads, and the wires to form a plurality of sealing bodies in which the external connection terminals are protruded from the rear surface to the outside and the part of the leads on which the reference mark is formed is exposed from the upper surface; and
(g) detaching the lead frame on which the plurality of sealing bodies are formed from the molding die, then cutting the lead frame, thereby singularizing the plurality of sealing bodies.
